(19) United States
(12) Patent Application Publication
(10) Pub. No.: US 2010/0175832 A1
(43) Pub. Date: Jul. 15, 2010

(54) Plasma processing apparatus and plasma generating apparatus

(75) Inventor: Ryoji Nishio, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi High-Technologies Corporation

(21) Appl. No.: 12/461,890

(22) Filed: Aug. 27, 2009

(30) Foreign Application Priority Data
Jan. 15, 2009 (JP) PCT/JP2009/050428
Apr. 6, 2009 (JP) 2009-091760

(51) Int. Cl. H01L 21/306

(52) U.S. Cl. 156/345.49

(57) ABSTRACT

The invention provides an ICP source plasma processing apparatus having improved the uniformity and ignition property of plasma. A plasma processing apparatus comprises a vacuum processing chamber 1, a dome-shaped vacuum reactor top member 12 formed of an insulating material, a gas supply port 3, a high frequency induction antenna (antenna) 7 disposed on an upper portion outside the vacuum processing chamber 1, magnetic coils 81 and 82 for forming a magnetic field with in the vacuum processing chamber 1, a yoke 83 for controlling the distribution of magnetic field, a plasma generating high frequency power supply 51 for supplying high frequency current to the antenna 7, and a power supply for supplying power to the magnetic field coil, wherein the antenna 7 is divided into n-number of high frequency induction antenna elements 7-1 (not shown), 7-2, 7-3 (not shown) and 7-4, the divided antenna elements are arranged tandemly on a single circumference, high frequency currents having wavelengths respectively delayed by λ/n of the wavelength of the high frequency power supply are supplied via delay means 7-2 through 7-4 to the respective tandemly arranged antenna elements in order in a right rotation, and a magnetic field is applied via the magnetic field coil so as to cause an ECR phenomenon.

The present application is based on and claims priorities of PCT international application No. PCT/JP2009/050428 filed Jan. 15, 2009 and Japanese patent application No. 2009-091760 filed on Apr. 6, 2009, the entire contents of which are hereby incorporated by reference.

### BACKGROUND OF THE INVENTION

1. Field of the Invention

The present invention relates to a plasma processing apparatus and a plasma generating apparatus using inductively coupled electron cyclotron resonance plasma. Specifically, the present invention characterizes in the structure of a high frequency induction antenna and the structure of a plasma reactor of the plasma processing apparatus and the plasma generating apparatus using inductively coupled electron cyclotron resonance plasma.

2. Description of the Related Art

In response to the miniaturization of semiconductor devices, the process conditions for realizing a uniform processing result within the wafer plane (process window) in plasma processing has become narrower year after year, and there are demands to control the process conditions more accurately in current plasma processing apparatuses. In order to respond to these demands, an apparatus capable of controlling the distribution of plasma, the dissociation of process gas and the surface reaction within the reactor with extremely high accuracy is required.

Currently, the typical plasma source used for such plasma processing apparatus is an inductively coupled plasma (hereinafter referred to as ICP) source. According to the ICP source, at first, a high frequency current I supplied to the high frequency induction antenna generates an induction magnetic field H around the antenna, and the induction magnetic field H creates an induction electric field E. At this time, when electrons exist in the space in which plasma should be generated, the electrons are driven by the induction electric field E, so as to ionize the gas atoms (molecules) and generate ion-electron pairs. The electrons thus formed are re-driven with the original electrons by the induction electric field E, by which further ionization is promoted. Finally, electron avalanche of the ionization phenomenon occurs, and plasma is generated. The area in which the density of plasma is highest is the space within the plasma generation space where the induction magnetic field H and the induction electric field E are strongest, that is, the space nearest the antenna. Further, the intensity of induction magnetic field H and induction electric field E attenuates by double the distance from a path of the current I flowing in the high frequency induction antenna. Therefore, the intensity distribution of the induction magnetic field H or the induction electric field E, consequently the plasma distribution, can be controlled via the shape of the antenna.

As described, the ICP source generates plasma by the high frequency current I flowing in the high frequency induction antenna. Generally when the number of turns of the high frequency induction antenna is increased, the inductance will rise and the current will drop, but the voltage will rise. When the number of turns is reduced, the voltage will drop but the current will rise. In designing the ICP source, the preferable level of current and voltage is determined not only from the viewpoint of uniformity, stability and generation efficiency of plasma, but also from various viewpoints of mechanical and electrical engineering. For example, the increase of current causes problems such as heating, power loss, and current-proof property of the variable capacitor used in the matching circuit. On the other hand, the increase of voltage causes problems such as abnormal discharge, influence of capacitive coupling of the high frequency induction antenna and plasma, and the dielectric-strength property of the variable capacitor. Therefore, designers of ICP sources must take into consideration the current-proof property and the dielectric-strength property of the electric elements such as the variable capacitors used in the matching circuit, the cooling of the high frequency induction antenna and the abnormal discharge thereof, upon determining the shape and number of turns of the high frequency induction antenna.

Such ICP source is advantageous in that the intensity distribution of the induction magnetic field H and induction electric field E created by the antenna, that is, the distribution of plasma, can be controlled via the turns and shapes of the high frequency induction antenna. Various design efforts of ICP sources have been provided.

One practical example is a plasma processing apparatus capable of processing a substrate placed on a substrate electrode using the ICP source. In the disclosed plasma processing apparatus, a portion of or all the high frequency induction antenna is formed of a multi-spiral shaped antenna so as to achieve a more uniform plasma, and deterioration of power efficiency via a matching parallel coil of the matching circuit for the high frequency induction antenna is minimized so as to reduce temperature rise (refer for example to patent document 1).

Further, an arrangement in which a plurality of identical high frequency induction antennas are disposed in parallel at fixed angular intervals has been proposed. For example, three high frequency induction antennas are disposed at angles of 120°, according to which the circumferential uniformity can be improved (refer for example to patent document 2). The disclosed high frequency induction antennas are wound vertically, wound in a plane, or wound around a dome. As disclosed in patent document 2, when a plurality of identical antenna elements are connected in parallel in the electric circuit, there is an advantage in that the total inductance of the high frequency induction antennas composed of a plurality of antenna elements is reduced.

Further, the high frequency induction antenna is arranged by connecting two or more identical antenna elements in parallel in the electric circuit, and the center of the antenna elements is arranged concentrically or radially so that their center coincide with the center of the object being processed, and the input terminals of the respective coil elements are disposed at fixed angular intervals obtained by dividing 360° by the number of coil elements, wherein the coil elements have three-dimensional structures extending in the radial and height direction (refer for example to patent document 3).

With respect to the ICP source, an electron cyclotron resonance (hereinafter referred to as ECR) plasma source is a plasma generating apparatus utilizing the resonant absorption of electromagnetic waves via electrons, characterized in that it has high absorption efficiency of electromagnetic energy, superior ignition property, and that a high density plasma can be obtained. Currently, apparatuses utilizing microwaves (2.45 GHz) or electro magnetic waves in the UHF or VHF band are developed. In many cases, radiation of electromagnetic waves into the discharge space is performed by adopting non-electrode discharge using waveguides for microwaves (2.45 GHz), and a dopting parallel plate capacitively coupled discharge applying capacitive coupling of plasma and electrodes radiating electromagnetic waves for UHF and VHF.

A plasma source utilizing the ECR phenomenon adopting high frequency induction antennas is also proposed. According to this plasma source, plasma is generated via waves called whistler waves which are a type of waves accompanying ECR phenomenon. Whistler waves are also called helicon waves, and the plasma source utilizing such waves is also called a helicon plasma source. One example of the arrangement of a helicon plasma source includes winding a high frequency antenna around the side wall of a cylindrical vacuum reactor, and applying a relatively low frequency, such as a high frequency power of 13.56 MHz, to the antenna, and further applying a magnetic field. At this time, the high frequency induction antenna generates electrons rotating in a right direction during a half cycle of the single cycle of 13.56 MHz, and generates electrons rotating in a left direction during the remaining half cycle. Of the two types of electrons, the mutual action between electrons rotating in the right direction and the magnetic field causes ECR phenomenon. However, the helicon plasma source is not suited for industrial use, since it has the following drawbacks: the time in which the ECR phenomenon occurs is limited to the half cycle of the high frequency, the place in which ECR occurs is diffused and the absorption length of the electromagnetic waves is long, so that a long cylindrical vacuum reactor is required, making it difficult to obtain uniform plasma, and the plasma property changes in steps in addition to the use of a long vacuum reactor, so that it is difficult to control the plasma to have a desirable plasma property (such as the electron temperature and the dissociation of gas).

A vertically long vacuum reactor specific for use with a helicon plasma source has been proposed (for example, refer to patent document 5). However, according to the art disclosed in the document, there is no use of high frequency induction antennas, and the helicon waves are generated via a method for controlling the phase of the voltage applied to a patch electrodes capacitively coupled with plasma. Further, in order to compensate for the drawback of the above-mentioned controllability of plasma distribution, two or more groups of electrodes are disposed along the vertically long vacuum reactor with an interval therebetween corresponding to the function of the helicon wave wavelength. However, regardless of whether an inductively coupled antenna or capacitively coupled patch electrodes are used, as long as helicon waves are used, the vertically long vacuum reactor must be used, by which the controllability of the plasma is deteriorated. This drawback is reflected clearly in patent document 5. In order to improve the controllability of plasma using the vertically long vacuum reactor, it is necessary to provide an extremely complex electrode and magnetic field arrangement, which is also reflected clearly in patent document 5.

There are many ways to create a rotating electric field in order to generate electrons rotating in the right direction. A simple method using patch antennas as disclosed in patent document 5 has been known for a long time, wherein n-number of (for example, 4) patch-like (small planes having circular or rectangular shapes) antennas are arranged on a circumference, and voltages having a frequency of the electromagnetic waves to be irradiated are supplied to the antennas so that the phases thereof are sequentially displaced by π/n (for example, π/4), according to which circularly polarized electromagnetic waves rotating in the right direction cab be irradiated.

At first, a method for actively generating an electric field rotating in the right direction will be described. When an active antenna exists, both a near field (both the electric field and the magnetic field) and a far field (electromagnetic waves) are formed around the antenna. The type and the intensity of the fields to be generated depends on the design and the way of use of the antenna. At this time, when the plasma and the antenna are capacitively coupled, the main process of power transportation to the plasma will be the electric field (near field). Further, when the plasma and the antenna are inductively coupled, the main process of power transportation to the plasma will be the magnetic field (near field) If neither capacitive coupling nor inductive coupling are performed actively, the main process of power transportation to the plasma will utilize far field. The following illustrates a method for generating an electric field rotating in the right direction using an electromagnetic wave radiation, an electric field and a magnetic field.

### (1) Electromagnetic Wave Radiation (Far Field)

Far field refers to electromagnetic waves that can be propagated to a far distance. This method includes a case where an electromagnetic field having actively circularly-polarized waves rotated in the right direction is discharged into the generation space of plasma, and a case where the electromagnetic field does not have actively circularly-polarized waves rotated in the right direction but utilizes the circularly-polarized waves rotating in the right direction included in the electromagnetic waves. The method for arranging n-number of patch antennas as described is an example of the former case, and the prior art non-electrode ECR discharge using microwaves is an example of the latter case. The plasma and the antenna are not actively coupled so that the near field will not get in the way. The irradiated electromagnetic waves are simply entered to the plasma. General antennas such as patch antennas and dipole antennas (refer to patent document 4: however, the art does not actively rotate the electromagnetic field in the right direction) can be used. According to this method, the following (A), (B) and (C) can be said.
(A) Power is applied to the antenna (electrode). In order to enhance the radiation efficiency of the electromagnetic field, in many cases, the resonance of antenna is utilized actively. When resonance is not used, the radiation efficiency of electromagnetic waves is not good, so it is not preferable for practical use. The radiated electromagnetic waves do not actively head toward the plasma (basically, the electromagnetic waves are propagated to a far distance, so that they are oriented to various directions), so they are not efficiently absorbed by plasma, and they cannot be used to transfer a large amount of power. In order to transfer a large amount of power, a waveguide in which the direction of propagation of the electromagnetic waves is restricted is mainly used. However, the size of the waveguide is determined by the wavelength of the electromagnetic waves, so that when a frequency smaller than microwaves is used, the size of the waveguide will be too large, so the application of waveguides is limited.
(B) When an electrode (antenna) is used instead of the waveguide, a terminal for applying power to the electrode is provided. A terminal for grounding the electrode may or may not be provided. This is determined by the method in which the resonance of antennas is generated.
(C) Regardless of whether antennas are provided, the limit of penetration of electromagnetic waves radiated into plasma is determined by the cutoff density nc (m⁻³), and in this case, the electromagnetic waves penetrate through the plasma to the skin depth. The skin depth is 138 mm when the frequency is 200 MHz and the resistivity of plasma is 15 Ωm, which is greater by some digits than the sheath (which is a few mm or smaller). In other words, it penetrates further into the plasma compared to the case of capacitive coupling mentioned later.

The relationship between the frequency f of electromagnetic waves and the cutoff density nc is illustrated in FIG. 26. In the area smaller than microwaves, the cutoff density nc is generally smaller than the industrially used plasma density (10¹⁵⁻¹⁷m⁻³). In other words, the electromagnetic waves smaller than microwaves cannot be propagated freely through normal plasma, and penetrate to the skin depth.

### (2) Electric Field (Near Field)

In order to generate an electric field, an active electrode generating near field (electric field) is required, such as patch electrodes (refer for example to patent document 5) and parallel plate electrodes. In this case, the electric field (voltage generated in the electrode) must be strong (high), so the load of the electrode must be set to high impedance. In other words, the electrode used here must be designed to be capacitively coupled with plasma, but to not be coupled with earthed components as much as possible. In other words, it is generally not possible to earth even a portion of the electrode, or to earth the same by connecting a capacitor or a coil thereto. The electric field is a near field, so by devising the positional relationship between the electrode and plasma, it is possible to transfer a large amount of power efficiently to plasma, but in order to enhance capacitive coupling, it must have a sufficiently large area (a large electrostatic capacity) with respect to plasma. The capacitive coupling of the electrode and plasma is used, so not only antennas (electrodes capable of irradiating electromagnetic waves) but electrodes (equivalent to electrodes of a capacitively coupled parallel plate plasma source) simply generating an electric field (near field) can be used even when its ability to radiate electromagnetic waves is weak.

The following can be said with respect to this method.
(A) A voltage is applied to the electrode. When the circularly-polarized waves rotating in the right direction is actively used, the voltage must be phase-controlled.
(B) The electrode only includes a terminal for applying voltage, and does not include other terminals such as a terminal for grounding the electrode.
(C) The capacitively coupled electric field is shielded by the collective motion of electrons (sheath). In order to reduce such shield, a magnetic field perpendicular to the electric field in a sheath must be applied to restrict the electron motion. In other words, by restricting the electron motion, the wavelength of the electric field within the plasma is extended.
(D) According to the art disclosed in patent document 5, it can be concluded that an electrode capacitively coupled with plasma is used, based on the following arguments.
(D-1) Voltage is utilized as high frequency signals. This means that the high frequency energy is converted directly to voltage or electric field and transmitted to the plasma. This means that the electrode is capacitively coupled with plasma. Further, when inductive coupling is used, current must be used as high frequency. This is because inductive coupling is performed via induction magnetic field, and the induction magnetic field is generated not via voltage but via high frequency current.
(D-2) The document discloses a shielding phenomenon caused by electron motion, which means that the electrode is capacitively coupled with plasma. This describes that the shielding can be reduced via static magnetic field, which is possible only when the electrode is capacitively coupled with plasma. This is because it is impossible to change the skin depth via static magnetic field. High frequency induction magnetic field can only be reduced via high frequency induction magnetic field, and cannot be reduced via static magnetic field. This is because a magnetic field has a physical quantity capable of being subjected to addition and subtraction, but it is impossible to reduce the high frequency induction magnetic field (in other words, a variable value) via a static magnetic field (in other words, a constant value). The skin effect of plasma itself is the shielding effect of high frequency magnetic field components included in the electromagnetic field, and the skin effect itself is brought about by the high frequency induction magnetic field (which has an opposite polarity as the induction magnetic field being applied via current, so through addition, it reduces the induction magnetic field being generated by current) generated in the plasma.
(D-3) It is disclosed that the electrode used in patent document 5 is not an antenna. This means that the electrode being used mainly utilizes a near field. In other words, it is either an induction electric field or an induction magnetic field described hereafter.
(D-3-1) Patent document 5 discloses using patch-like electrodes having small areas in which the efficiency of radiating electromagnetic waves is not good. This means that the used electrode mainly utilizes the near field, and therefore, it is either an induction electric field or an induction magnetic field described hereafter. However, in the case of an electric field, a wide area (large electrostatic capacity) is required to increase the coupling with plasma, whereas in the case of a magnetic field, a path for supplying current must be provided longitudinally in parallel with plasma in order to realize transformer-coupling (inductive coupling). Patent document 5 only realizes capacitive coupling based on the shape of the electrode. There is no description nor drawing indicating that the patched electrodes are earthed. As described in (D-3-2), the size of the patch-like electrode is shorter than the wavelength of the high frequency, and the voltage generated in the patch-like electrode is varied by the frequency of the applied high frequency, but instantaneously, a constant voltage not being influenced by the wavelength is generated through the whole electrode, and a constant current is flown therein. The patch electrodes create as near field both intense induction electric field and weak induction magnetic field, but in that case, the induction electric field has an area capacitively coupled strongly with plasma, but the patch electrodes do not have a path length enabling to perform transformer-coupling strongly with plasma.
(D-3-2) An example using 13.56 MHz is disclosed, but the wavelength of 13.56 MHz is approximately 22 m, and the patched electrodes in the drawing cannot be considered as being resonant with this wavelength (if it is resonating, the size of the electrode must be ½ or ¼ of the wavelength, and resonance will not occur if no active resonating means as shown in patent document 4 is applied. Further, there is a description that the electrode is not an antenna, so the patch electrode cannot be considered to be resonating). Further, there is no plasma processing apparatus capable of performing determined processes for forming semiconductor devices requiring such a large electrode. This means that the utilized electrodes mainly use near field (either induction electric field or induction magnetic field described later). However, in the case of electric fields, a wide area (large electrostatic capacity) is required to enhance coupling with plasma, whereas in the case of magnetic fields, a path for supplying current must be formed longitudinally in parallel with plasma for realizing transformer-coupling (inductive coupling). The shape of the electrodes is patch-like, and there is no current path for realizing the transformer-coupling with plasma. In other words, the patch-like electrodes are capacitively coupled with plasma.
(D-3-3) Further, there is no description that the patch-like electrode is earthed. According thereto, the current flowing through the patch-like electrodes is flown via the plasma to an earth. In other words, plasma is the load of the patch-like electrodes, and the current varies greatly by the impedance of the generated plasma. As known well, in inductively coupled plasma, current is basically supplied to one end of the path being inductively coupled with plasma, while the other end is earthed. Accordingly, current flowing in the path is mainly directly supplied to the earth, and a large current is generated by the earth (low impedance of load). The large current is used to generate the induction magnetic field, through which power can be transferred efficiently to plasma. Of course, it is possible to separate the earth end from the earth and to insert a capacitor, but it still offers power to be transferred efficiently to plasma by generating an intense induction magnetic field by the large current generated by devising electric circuits. In other words, since the document lacks to provide any description nor drawings that the patched electrodes are earthed, it means that the patched electrode is mainly capacitively coupled with plasma.

### [Patent Documents]

[Patent document 1] Japanese patent application laid-open publication No.08-083696
[Patent document 2] Japanese patent application laid-open publication No. 08-321490
[Patent document 3] Japanese patent application laid-open publication No. 2005-303053
[Patent document 4] Japanese patent application laid-open publication No. 2000-235900
[Patent document 5] Japanese patent No. 3269853
[Patent document 6] Japanese patent application laid-open publication No. 11-135438

### [Non-Patent Documents]

[Non-patent document 1] L. Sansonnens et al., Plasma Sources Sci. Technol. 15, 2006, pp 302
[Non-patent document 2] J. Hoopwood et al., J. Vac. Sci. Technol., All, 1993, pp 147
[Non-patent document 3] M. Yamashita et al., Jpn. J. Appl. Phys., 38, 1999, pp 4291
[Non-patent document 4] K. Suzuki et al., Plasma Sources Sci. Technol., 9, 2000, pp 199

### SUMMARY OF THE INVENTION

Regarding the prior art of generating an electric field rotating in the right direction, there has not been an art to create an electric field actively rotating in the right direction using an induction magnetic field (near field). Even further, there has not been developed an art to cause ECR phenomenon using the induction electric field actively rotating in the right direction crated via an induction magnetic field. The induction magnetic field is generated via current, so a completely reverse design with respect to using electric field is required. In other words, the use of induction magnetic field requires an active electrode for generating an intense near field (magnetic field), and the current must be strong, so that the load of the electrode must be of low impedance. In other words, the electrode used here must be inductively coupled (transformer-coupled) with plasma, and it must be actively earthed or earthed via capacitors or coils. The use of induction magnetic field is near field, so by devising the positional relationship with plasma, a large power can be transferred efficiently to plasma. According to this method, in order to strengthen inductive coupling, a path length (coil length) sufficient for coupling with plasma is required. This method utilizes the induction coupling of electrode and plasma (transformer-coupling), so it is possible to use not only antennas (electrodes capable of radiating electromagnetic waves) but also electrodes (coils) merely generating magnetic field (near field) having a weak ability to irradiate electromagnetic waves. The following can be said for the present method.
(A) A phase-controlled current is applied to the electrode.
(B) The electrode has a terminal for applying current and another terminal for actively supplying a large current from the electrode to an earth portion. This terminal is either earthed directly or earthed via capacitors or coils.
(C) The inductively coupled electric field is shielded via skin effect similar to far field. This shield cannot be prevented via static magnetic field.

In an ICP source, when a high frequency current I is circulated around a high frequency induction antenna, it is flown into the plasma or earth via floating capacity and causes loss. This can cause the induction magnetic field H to have various intensity distributions in the circumferential direction, and as a result, a phenomenon where the uniformity of plasma in the circumferential direction is deteriorated may become significant. This phenomenon, which is a wavelength shortening phenomenon that appears as a reflected wave effect or a skin depth effect, not only influenced by the permittivity of the space surrounding the high frequency induction antenna but the magnetic permeability thereof. This phenomenon is a general phenomenon that occurs also in normal high frequency transmission cables such as coaxial cables, but when the high frequency induction antenna is either inductively coupled or capacitively coupled with plasma, the wavelength shortening effect thereof will appear more significantly. Further, not only in ICP sources but in general plasma sources such as the ECR plasma sources or the parallel plate capacitively coupled plasma sources, the traveling waves traveling toward the antenna or the interior of the vacuum reactor and the reflected waves are superposed to generate standing waves in the space surrounding the antenna irradiating high frequencies. This is caused by the reflected waves being reflected from the antenna terminal portion, the plasma and many portions in the vacuum reactor in which the high frequencies are irradiated. The standing waves also relate significantly to the wavelength shortening effect. In this state, in the case of ICP sources, even if a frequency of 13.56 MHz having a long wavelength of approximately 22 m is used as the radio frequency of the RF power supply, if the high frequency induction antenna length exceeds 2.5 m, standing waves accompanying a wavelength shortening effect are generated in the antenna loop. Therefore, the current distribution within the antenna loop becomes uneven, and the plasma density distribution also becomes uneven.

In an ICP source, the high frequency current I flowing in the antenna has its phase or direction of flow reversed periodically, and along there with, the direction of the induction magnetic field H (induction electric field E), that is, the direction in which the electrons are driven, is also reversed. In other words, the electrons temporarily stop and then are accelerated in the opposite direction per every half cycle of the applied high frequency. According to such condition, when electron avalanche ionization during a certain half cycle of the high frequency is insufficient, it is difficult to obtain a sufficiently high density plasma when the electrons are temporarily stopped. This is because when the electrons are decelerated and temporarily stopped, the generation efficiency of plasma drops. Generally, as described earlier, the ignition property of plasma is not good according to the ICP source compared to the ECR plasma source or the capacitively coupled parallel plate plasma source. The generation efficiency of plasma is deteriorated every half cycle of high frequency waves in the same manner also according to a helicon plasma source using inductive coupling without being phase-controlled.

As described, there are many devices for improving the plasma uniformity using the ICP source, but the devising thereof causes the arrangement of the high frequency induction antenna to become complex, and will not workout as industrial apparatus. Further, the prior art is not intended to significantly improve the ignition property of plasma while maintaining a good plasma uniformity, and therefore, the problem of inferior ignition property is not solved.

On the other hand, the ECR plasma source has a short wave length, and a complex electric field distribution is easily generated within the apparatus, so it is difficult to achieve a uniform plasma.

Since the wavelength of microwaves (2.45 GHz) is short, in large-scale ECR plasma source, the microwaves are propagated within the discharge space via various high order propagation modes. Thus, electric fields are locally concentrated at various locations within the plasma discharge space, and high density plasma occurs at these portions. Further, microwaves reflected at the interior of the plasma apparatus and returning thereto are superposed with the electric field distribution by the high order propagation mode of incident microwaves by which standing waves are generated, so that the electric field distribution within the apparatus may become more complex. By the above two reasons, it is generally difficult to obtain a uniform plasma property with in a large diameter area. Further, once such complex electric field distribution occurs, it is actually impossible to control the electric field distribution and to change the same to an electric field distribution preferable for processing. This is because the structure of the apparatus must be changed so as not to cause high order propagation modes or to prevent reflected waves reflected and returning from the interior of the apparatus from forming a complex electric field distribution. A single apparatus structure almost never corresponds suitably to various discharge conditions. Further, in order to generate ECR discharge via microwaves (2.45 GHz), a magnetic field as intense as 875 Gauss is required, and the structure including power consumed by the coils generating such magnetic field and yoke becomes extremely large.

Further, regarding magnetic field intensity, relatively weak magnetic field is required for UHF and VHF, so that the significance of the problem is relieved. However, even by using UHF or VHF having a relatively long wavelength, the problem of standing waves is serious, wherein the electric field distribution within the discharge space becomes uneven, the generated plasma density distribution becomes uneven, and the process uniformity becomes a problem. Regarding this problem, theoretical and experimental studies are still performed (for example, refer to non-patent document 1).

As described, according to prior art ICP sources, means for generating plasma with advantageous uniformity have been examined, but such means will require a complex antenna structure, and will deteriorate the ignition property of plasma. On the other hand, ECR plasma sources have advantageous ignition property, but the high-order propagation mode of the electromagnetic waves and the plasma uniformity via standing waves are not good.

The present invention aims at solving the above problems, by providing a plasma processing apparatus using an ICP source in which the ECR discharge phenomenon can be utilized. Thereby, the antenna structure can be optimized via minimum schemes, by which the uniformity of plasma is improved and the ignition property of plasma is significantly improved.

In other words, the present invention provides a uniform plasma source with superior ignition property even in a plasma processing apparatus having a large diameter.

As a first step for solving the problems mentioned above, the present invention provides a plasma processing apparatus comprising a vacuum reactor constituting a vacuum processing chamber for housing a sample, a gas supply port for introducing a processing gas into the vacuum processing chamber, a high frequency induction antenna disposed outside the vacuum processing chamber, a magnetic field coil for forming a magnetic field within the vacuum processing chamber, a plasma generating high frequency power supply for supplying high frequency current to the high frequency induction antenna, and a power supply for supplying power to the magnetic field coil having high frequency current supplied to the high frequency induction antenna from the high frequency power supply and having a magnetic field applied thereto so as to turn the gas supplied into the vacuum processing chamber into plasma for subjecting the sample to plasma processing, wherein the vacuum processing chamber comprises a vacuum processing chamber top member fixed air tightly to an upper portion of the vacuum reactor, the vacuum processing chamber top member composed of dielectric material having a planar shape, a hollow semispherical shape, a rotated trapezoidal shape, or a cylindrical shape with a bottom, and the high frequency induction antenna being divided into n-number (n being an integer of n≧2) of high frequency induction antenna elements, the divided high frequency induction antenna elements being arranged tandemly on a circumference, wherein high frequency currents sequentially delayed by λ(wavelength of the high frequency power supply)/n in a fixed direction with respect to the direction of the line of magnetic force are supplied to the respective high frequency induction antenna elements arranged tandemly. Thereby, a rotating induction electric field E rotating in a right direction with respect to the direction of line of magnetic force of a magnetic field B formed by supplying power to the magnetic field coil is created via the high frequency current, and by the rotating induction electric field, the electrons in the plasma are rotated in the right direction with respect to the direction of the line of magnetic force. At this time, the rotation frequency of the rotation induction electric field E and the electron cyclotron frequency via the magnetic field B are designed to correspond to each other, and plasma is generated by arranging a plurality of antennas and a magnetic field so that the induction electric field E and the magnetic field B arbitrarily satisfy a relationship of E×B≠0.

The second step for solving the problems of the prior art is to further apply a magnetic field B to the electrons rotating in the right direction, to thereby cause Larmor motion of the electrons. Larmor motion is a motion in the right rotational direction based on E×B drift, and in order for this motion to occur, the induction electric field E and the magnetic field B must satisfy a relationship of E×B≠0. The direction of application of the magnetic field B is the direction in which the induction electric field E rotates in the right direction with respect to the direction of the line of magnetic force of the magnetic field B. When these conditions are satisfied, the rotating direction of the induction electric field E in the right direction and the direction of rotation of the Larmor motion correspond. Further, this change of magnetic field B must have a variation frequency fB satisfying a relationship of 2πfB<<ωc with respect to the rotation frequency (electron cyclotron frequency ωc) of the Larmor motion. In addition to applying the magnetic field B, by causing an electron cyclotron resonance phenomenon to occur by having the electron cyclotron frequency ωc of the magnetic field intensity and the rotation frequency f of the rotating induction electric field E corresponding so as to satisfy 2πf=ωc, the above-mentioned problems can be solved.

In order to solve the problems mentioned above, the present invention provides a plasma processing apparatus comprising a cylindrical vacuum reactor constituting a vacuum processing chamber for housing a sample, a gas supply port for introducing a processing gas into the vacuum processing chamber, a high frequency induction antenna disposed outside the vacuum processing chamber, a magnetic field coil for forming a magnetic field within the vacuum processing chamber, a plasma generating high frequency power supply for supplying high frequency current to the high frequency induction antenna, and a power supply for supplying power to the magnetic field coil, wherein high frequency current is supplied to the high frequency induction antenna from the high frequency power supply so as to turn the gas supplied into the vacuum processing chamber into plasma for subjecting the sample to plasma processing, wherein the high frequency induction antenna being divided into n-number (n being an integer of n≧2) of high frequency induction antenna elements are arranged tandemly along a circumference being concentrically disposed with the vacuum reactor, high frequency currents sequentially delayed by λ(wavelength of the high frequency power supply)/n are supplied in a fixed direction to the tandemly arranged high frequency induction antenna elements, and power is supplied to the magnetic coil so as to form a magnetic field, by which plasma is generated and the sample is subjected to plasma processing.

Further, the present invention provides a plasma processing apparatus comprising a cylindrical vacuum reactor constituting a vacuum processing chamber for housing a sample, a gas supply port for introducing a processing gas into the vacuum processing chamber, a high frequency induction antenna disposed outside the vacuum processing chamber, a magnetic field coil for forming a magnetic field within the vacuum processing chamber, a plasma generating high frequency power supply for supplying high frequency current to the high frequency induction antenna, and a magnetic field coil power supply for supplying power to the magnetic field coil, where in the high frequency induction antenna being divided into n-number (n being an integer of n≧2) of high frequency induction antenna elements are arranged tandemly along a circumference being concentrically disposed with the vacuum reactor, wherein high frequency currents sequentially delayed by λ(wavelength of the high frequency power supply)/n are supplied in a fixed direction to the tandemly arranged high frequency induction antenna elements, and high frequency currents are supplied to the high frequency induction antenna from the high frequency power supply, so as to turn the gas supplied into the vacuum processing chamber to plasma and to subject the sample to be processed to plasma processing, wherein the high frequency induction antenna and the magnetic field are arranged to satisfy a relationship of E×B≠0 between the induction electric field E generated by the antenna and the magnetic field B.

Further, the present invention provides a plasma processing apparatus comprising a cylindrical vacuum reactor constituting a vacuum processing chamber for housing a sample, a gas supply port for introducing a processing gas into the vacuum processing chamber, a high frequency induction antenna disposed outside the vacuum processing chamber, a magnetic field coil for forming a magnetic field within the vacuum processing chamber, a plasma generating high frequency power supply for supplying high frequency current to the high frequency induction antenna, and a magnetic field coil power supply for supplying power to the magnetic field coil, wherein the high frequency induction antenna being divided into n-number (n being an integer of n≧2) of high frequency induction antenna elements are arranged tandemly along a circumference being concentrically disposed with the vacuum reactor, wherein high frequency currents sequentially delayed by λ(wavelength of the high frequency power supply)/n are supplied in a fixed direction to the tandemly arranged high frequency induction antenna elements, and high frequency currents are supplied to the high frequency induction antenna from the high frequency power supply, so as to turn the gas supplied into the vacuum processing chamber to plasma and to subject the sample to plasma processing, wherein the rotation frequency f of the rotating induction electric field E and the electron cyclotron frequency ωc by the magnetic field B are set to correspond so that 2πf=ωc. Thereby, electrons are capable of absorbing high frequency power by electron cyclotron resonance, and the problems of the prior art can be solved.

Next, the present invention provides a plasma processing apparatus comprising a cylindrical vacuum reactor constituting a vacuum processing chamber for housing a sample, a gas supply port for introducing a processing gas into the vacuum processing chamber, a high frequency induction antenna disposed outside the vacuum processing chamber, a magnetic field coil for forming a magnetic field within the vacuum processing chamber, a plasma generating high frequency power supply for supplying high frequency current to the high frequency induction antenna, and a magnetic field coil power supply for supplying power to the magnetic field coil, wherein the high frequency induction antenna being divided into n-number (n being an integer of n≧2) of high frequency induction antenna elements are arranged tandemly along a circumference being concentrically disposed with the vacuum reactor, wherein high frequency currents sequentially delayed by λ(wavelength of the high frequency power supply)/n are supplied in a fixed direction to the tandemly arranged high frequency induction antenna elements, and high frequency currents are supplied to the high frequency induction antenna from the high frequency power supply, so as to turn the gas supplied into the vacuum processing chamber to plasma and to subject the sample to plasma processing, wherein the high frequency induction antenna and the magnetic field are designed so that the direction of rotation of the induction electric field E generated by the antenna is rotated in the right direction with respect to the line of magnetic force of the magnetic field B formed by the magnetic field coil.

Further, the present invention provides a plasma generating apparatus comprising a vacuum processing chamber, and a plurality of high frequency induction antennas disposed outside the vacuum processing chamber to which high frequencies are supplied, wherein the induction electric field distribution formed within the vacuum processing chamber via the plurality of antennas rotates in a fixed direction within a magnetic field having a finite value.

Further, the present invention provides a plasma generating apparatus comprising a vacuum processing chamber, and a plurality of high frequency induction antennas disposed outside the vacuum processing chamber to which high frequencies are supplied, wherein the plurality of antennas are arranged in axial symmetry, the magnetic field distribution has an axially symmetric distribution, the axis of the plurality of antennas and the axis of the magnetic field distribution correspond, and the induction electric field distribution formed within the vacuum processing chamber rotates in a fixed direction.

The present invention further provides a plasma generating apparatus, wherein the direction of rotation of the induction electric field distribution that rotates in the fixed direction is a right direction rotation with respect to the direction of the line of magnetic force of the magnetic field.

The present invention further provides a plasma generating apparatus, wherein the plurality of antennas and the magnetic field are designed so that the induction electric field E formed via the plurality of antennas and the magnetic field B satisfy a relationship of E×B≠0.

The present invention further provides a plasma generating apparatus, wherein the rotation frequency f of the rotating induction electric field E formed via the plurality of antennas and the electron cyclotron frequency ωc via the magnetic field B correspond so that 2πf=ωc.

Further according to the present invention, according to the plasma processing apparatus, the magnetic field B can either be a static magnetic field or a varying magnetic field, but when it is a varying magnetic field, the variation frequency fB thereof must satisfy a relationship of 2πfB<<ωc with the rotation frequency (electron cyclotron frequency ωc) of the Larmor motion.

### BRIEF DESCRIPTION OF THE DRAWINGS

FIG. 1 is a vertical cross-sectional view illustrating an outline of the arrangement of a plasma processing apparatus to which the present invention is applied;

FIG. 2A is a drawing illustrating the method for feeding power to a high frequency induction antenna element according to a first embodiment of the present invention;

FIG. 2B is a view illustrating the phase difference of high frequency currents supplied to high frequency induction antenna elements according to the power feed method of FIG. 2A;

FIG. 3A is a view (t=t1) illustrating the relation between the phase difference of high frequency currents supplied to high frequency induction antenna elements and a direction of the resultant induction electric field according to the present invention;

FIG. 3B is a view (t=t2) illustrating the relation between the phase difference of high frequency currents supplied to high frequency induction antenna elements and a direction of the resultant induction electric field according to the present invention;

FIG. 4 is a view illustrating the distribution of electric field intensity generated by a prior art high frequency induction antenna;

FIG. 5 is a view illustrating the distribution of electric field intensity generated by the high frequency induction antenna of the present invention;

FIG. 6 is a view illustrating the deformation example of the method for feeding power to the high frequency induction antenna elements according to the first embodiment of the present invention;

FIG. 7 is a view illustrating the method for feeding power to high frequency induction antenna elements according to a second embodiment of the present invention;

FIG. 8 is a view illustrating the method for feeding power to high frequency induction antenna elements according to a third embodiment of the present invention;

FIG. 9 is a view illustrating the method for feeding power to high frequency induction antenna elements according to a fourth embodiment of the present invention;

FIG. 10 is a view illustrating the method for feeding power to high frequency induction antenna elements according to a fifth embodiment of the present invention;

FIG. 11 is a view illustrating the method for feeding power to high frequency induction antenna elements according to a sixth embodiment of the present invention;

FIG. 12 is a view illustrating the method for feeding power to high frequency induction antenna elements according to a seventh embodiment of the present invention;

FIG. 13A is an explanatory view showing the state of ion distribution when the shape of the vacuum reactor top member is a planar according to the plasma processing apparatus of the present invention;

FIG. 13B is an explanatory view showing the state of change of ion distribution when the position of the high frequency induction antenna elements of FIG. 13A is changed;

FIG. 13C is an explanatory view showing the state of ion distribution of a deformation example when the shape of the vacuum reactor top member is a hollow semispherical shape according to the plasma processing apparatus of the present invention;

FIG. 13D is an explanatory view showing the state of ion distribution of a deformation example when the shape of the vacuum reactor top member is a rotated trapezoidal shape according to the plasma processing apparatus of the present invention;

FIG. 13E is an explanatory view showing the state of ion distribution of a deformation example when the shape of the vacuum reactor top member is a cylindrical shape with a bottom and the high frequency induction antenna elements are disposed on surrounding walls according to the plasma processing apparatus of the present invention;

FIG. 14 is an explanatory view showing an example where the shape of the vacuum reactor top member is a hollow semispherical shape according to the plasma processing apparatus of the present invention;

FIG. 15 is an explanatory view showing an example where the shape of the vacuum reactor top member is a rotated trapezoidal shape according to the plasma processing apparatus of the present invention;

FIG. 16 is an explanatory view showing an example where the shape of the vacuum reactor top member is a cylindrical shape with a bottom according to the plasma processing apparatus of the present invention;

FIG. 17 is an explanatory view showing the relationship between isomagnetic field plane (ECR plane) and the line of magnetic force formed according to the present invention;

FIG. 18A is an explanatory view showing the relationship between the ECR plane and the plasma generation area of an example where the vacuum reactor top member is planar and no magnetic field is applied according to the present invention;

FIG. 18B is an explanatory view showing the relationship between the ECR plane and the plasma generation area of an example where magnetic field is applied according to the example of FIG. 18A;

FIG. 18C is an explanatory view showing the relationship between the ECR plane and the plasma generation area of an example where the vacuum reactor top member is hollow semispherical shaped;

FIG. 18D is an explanatory view showing the relationship between the ECR plane and the plasma generation area of an example where the vacuum reactor top member is rotated trapezoidal shaped;

FIG. 18E is an explanatory view showing the relationship between the ECR plane and the plasma generation area of an example where the vacuum reactor top member is cylindrical shaped with a bottom and the high frequency induction antenna elements are disposed on the surrounding wall;

FIG. 19 is a view illustrating the method for feeding power to multiple sets of high frequency induction antenna elements according to an eighth embodiment of the present invention;

FIG. 20 is an explanatory view illustrating the method for feeding power to multiple sets of high frequency induction antenna elements according to a ninth embodiment of the present invention;

FIG. 21 is an explanatory view illustrating the method for feeding power to multiple sets of high frequency induction antenna elements according to a tenth embodiment of the present invention;

FIG. 22 is an explanatory view illustrating the method for feeding power to multiple sets of high frequency induction antenna elements according to an eleventh embodiment of the present invention;

FIG. 23A is an explanatory view showing an example where the vacuum reactor top member is planar and having multiple sets of high frequency induction antenna elements arranged according to the plasma processing apparatus of the present invention;

FIG. 23B is an explanatory view showing an example where the vacuum reactor top member is hollow semispherical shaped and a having multiple sets of high frequency induction antenna elements arranged according to the plasma processing apparatus of the present invention;

FIG. 23C is an explanatory view showing an example where the vacuum reactor top member is rotated trapezoidal shaped and having multiple sets of high frequency induction antenna elements arranged according to the plasma processing apparatus of the present invention;

FIG. 23D is an explanatory view showing an example where the arrangements of the multiple sets of high frequency induction antenna elements in the example shown in FIG. 23C is changed;

FIG. 23E is an explanatory view showing an example where the vacuum reactor top member is cylindrical shaped with a bottom and having multiple sets of high frequency induction antenna elements arranged in the circumference thereof according to the plasma processing apparatus of the present invention;

FIG. 23F is an explanatory view in which the arrangement of the multiple sets of high frequency induction antenna elements of the example shown in FIG. 23E is changed;

FIG. 23G is an explanatory view in which the arrangement of the multiple sets of high frequency induction antenna elements of the example shown in FIG. 23E is changed;

FIG. 24 is an explanatory view illustrating the method for feeding power to multiple sets of high frequency induction antenna elements arranged in a rectangle according to a twelfth embodiment of the present invention;

FIG. 25 is an explanatory view illustrating the method for feeding power to multiple sets of high frequency induction antenna elements arranged in a rectangle according to a thirteenth embodiment of the present invention;

FIG. 26 is an explanatory view illustrating the relationship between the frequency f of the electromagnetic waves and the cutoff density nc;

FIG. 27A is an explanatory view of the distribution of standing waves of the current and the voltage occurring in the antenna elements when the standing waves within a single antenna element cannot be ignored; and

FIG. 27B is an explanatory view of another example of distribution of standing waves of the current and the voltage occurring in the antenna elements when the standing waves within a single antenna element cannot be ignored.

### DETAILED DESCRIPTION OF THE PREFERRED EMBODIMENTS

The plasma processing apparatus according to the present invention is not restricted to application in the field of semiconductor device fabrication, and it can be applied to various fields of plasma processing, such as for manufacturing liquid crystal displays, for depositing various materials, and for treating surfaces. Here, we will illustrate preferred embodiments of the invention, taking the plasma etching apparatus for manufacturing semiconductor devices as an example.

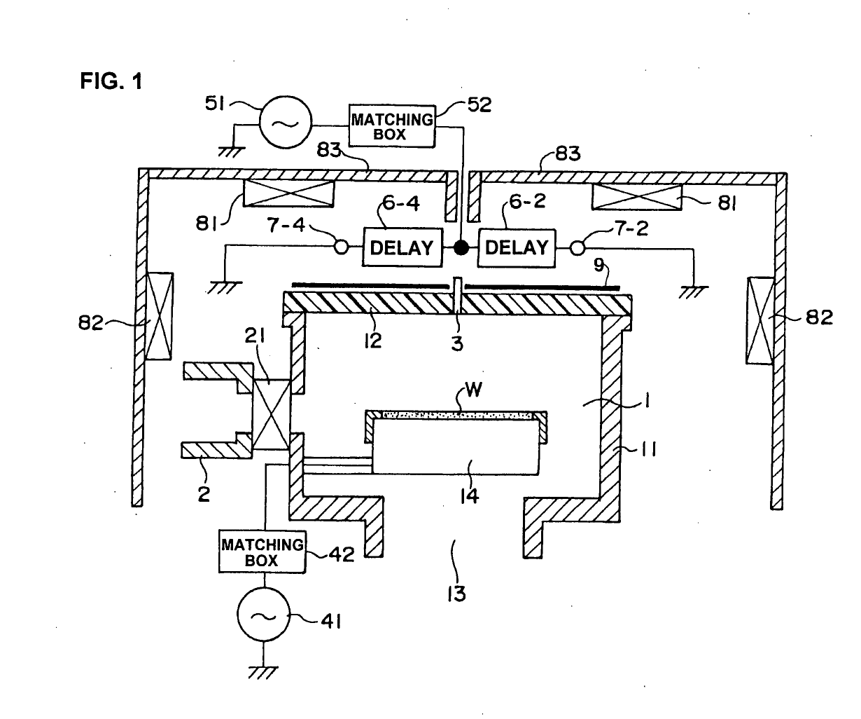

The outline of the structure of the plasma processing apparatus to which the present invention is applied will be described with reference to FIG. 1. A high frequency inductively coupled plasma (ICP) type plasma processing apparatus is composed of a cylindrical vacuum reactor 11 having a vacuum processing chamber 1 having its interior maintained to vacuum, a top member 12 of the vacuum processing chamber formed of an insulating material for introducing the electric field generated via high frequency into the vacuum processing chamber, an evacuation means 13 connected for example to a vacuum pump for maintaining the interior of the vacuum processing chamber to vacuum, an electrode (sample stage) 14 on which an object to be processed (semiconductor wafer) W is placed, a transfer system 2 having a gate valve 21 for transferring the semiconductor wafer W which is the object to be processed between the exterior and the interior of the vacuum processing chamber, a gas inlet port 3 for introducing processing gas, a bias high frequency power supply 41 for supplying bias voltage to the semiconductor wafer W, a bias matching box 42, a plasma generating high frequency power supply 51, a plasma generating matching box 52, a plurality of delay means 6-2, 6-3 (not shown) and 6-4, high frequency induction antenna elements 7-1 (not shown), 7-2, 7-3 (not shown) and 7-4 divided into multiple elements and tandemly arranged on a circumference of the vacuum processing chamber 1 and constituting a high-frequency induction antenna 7, electromagnets constituting an upper coil 81 and a lower coil 82 for applying magnetic field, a yoke 83 formed of a magnetic material for controlling the distribution of magnetic field, a faraday shield 9 for controlling the capacitive coupling of plasma and the high frequency induction antenna elements 7-1 (not shown), 7-2, 7-3 (not shown) and 7-4, and a magnetic field coil power supply not shown for supplying power to the electromagnets.

The vacuum reactor 11 is, for example, a vacuum vessel formed of an aluminum having its surface treated with alumite (anodized aluminum) processing or a stainless steel, which is electrically earthed. Further, it is also possible to perform surface treatments other than alumite processing, such as through use of other substances having high plasma resisting property (such as yttria: Y₂O₃). The vacuum processing chamber 1 comprises an evacuation means 13, and a transfer system 2 with a gate valve for carrying semiconductors W to be processed into and out of the chamber. In the vacuum processing chamber 1 is disposed an electrode 14 for placing thereon a semiconductor wafer W concentrically with the cylindrical vacuum reactor 11, which is positioned concentrically within the cylindrical vacuum reactor 11. The wafer W having been carried into the vacuum processing chamber through the transfer system 2 is carried onto the electrode 14, and fixed to the electrode 14. A bias high frequency power supply 41 is connected via a bias matching box 42 to the electrode 14 with the aim to control the energy of ions being incident on the semiconductor wafer W during plasma processing. The gas to be used for the etching process is introduced into the vacuum processing chamber 1 via the gas inlet port 3.

On the other hand, high frequency induction antenna elements 7-1 (not shown), 7-2, 7-3 (not shown) and 7-4 are disposed in an atmospheric area at a position opposing to the semiconductor wafer W via the vacuum reactor top member 12 formed of a planar insulating material such as quartz or alumina ceramics. The high frequency induction antenna elements 7-1 through 7-4 are disposed concentrically so that the center thereof corresponds to the center of the semiconductor wafer W. Although not shown in FIG. 1, the high frequency induction antenna elements 7-1 through 7-4 are composed of a plurality of antenna elements having identical shapes. The power feed ends A of the plurality of antenna elements are connected via a plasma generating matching box 52 to the plasma generating high frequency power supply 51, and the earth ends B thereof are connected to an earth potential in the exact same manner.

Delay means 6-2, 6-3 (not shown) and 6-4 for delaying the phase of the current flowing to the respective high frequency induction antenna elements 7-1 through 7-4 are disposed between the high frequency induction antenna elements 7-1 through 7-4 and the plasma generating matching box 52.

A refrigerant flow path for cooling means not shown is disposed on the vacuum reactor top member 12, wherein cooling is performed by passing fluids such as water, Fluorinert (registered trademark), air and nitrogen through the refrigerant flow path. The antenna, the vacuum reactor 11 and the wafer stage 14 are also objects of cooling and temperature control.

### Embodiment 1

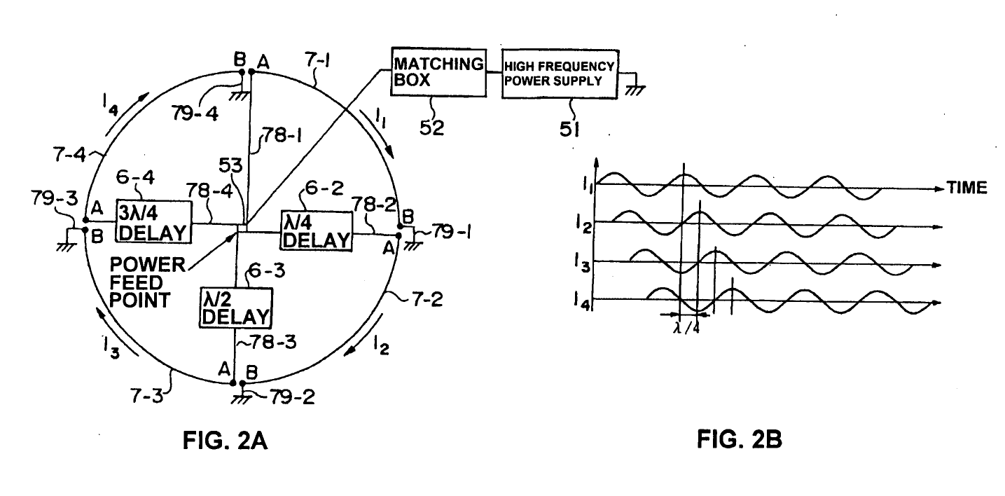

FIGS. 2A and 2B are referred to in describing the first preferred embodiment of the plasma processing apparatus according to the present invention. In the present embodiment, as shown in FIG. 2A illustrating a top view of FIG. 1, the high frequency induction antenna 7 is divided into n=4 (n being an integer of n≧2) high frequency induction antenna elements 7-1 through 7-4 on a single circumference. The power feed ends A or the earth ends B of the respective high frequency induction antenna elements 7-1 through 7-4 are disposed at intervals of 360°/4 (360°/n) in the clockwise direction, and high frequency currents are supplied from the plasma generating high frequency power supply 51 via the plasma generating matching box 52 and from a power feed point 53 via respective power feed ends A to the respective high frequency induction antenna elements 7-1, 7-2, 7-3 and 7-4. In the present embodiment, the respective earth ends B of the high frequency induction antenna elements 7-1 through 7-4 are respectively disposed at a distance of approximately λ/4 (λ/n) from the power feed ends A in the clockwise direction on the circumference. The length of each of the high frequency induction antenna elements 7-1 through 7-4 is not required to be λ/4 (λ/n), but it should preferably be equal to or smaller than λ/4 (λ/n) of the generated standing waves. According to the arrangement of the antenna, the length of each high frequency induction antenna element should be equal to or smaller than λ/2. A λ/4 delay circuit 6-2, a λ/2 delay circuit 6-3, and a 3λ/4 delay circuit 6-4 are inserted respectively between the power feed point 53 and the power feed ends A of the high frequency induction antennal elements 7-2, 7-3 and 7-4. According to this arrangement, the currents I₁, I₂, I₃ and I₄ supplied to the respective induction antenna elements 7-1 through 7-4 have phases sequentially delayed by λ/4 (λ/n) in order as shown in FIG. 2B. The electrons in the plasma driven by current I₁ is further driven by current I₂. Further, the electrons in the plasma driven by current I₃ is further driven by current I₄.

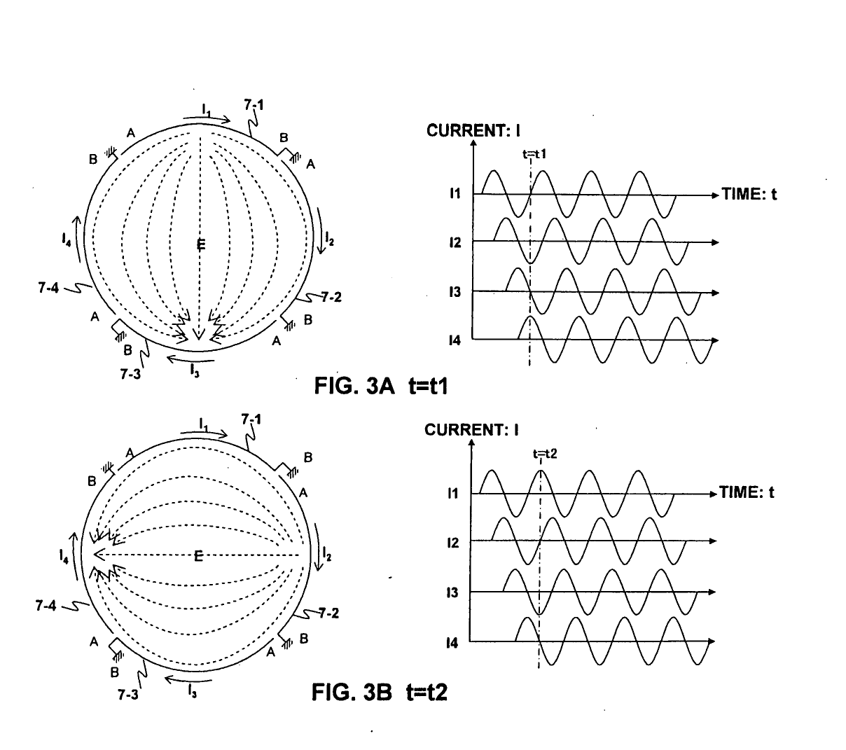

With reference to FIGS. 3A and 3B, the pattern in which the electrons in the plasma are driven using the high frequency induction antenna shown in FIGS. 2A and 2B is described. In FIGS. 3A and 3B, the arrangement of the power feed ends A and earth ends B of the high frequency induction antenna elements 7-1 through 7-4 is the same as that illustrated in FIGS. 2A and 2B. The currents I₁ through I₄ flowing in the respective induction antenna elements are all directed from the power feed ends A toward the earth ends B. The phases of currents I₁ through I₄ flowing to the respective induction antenna elements are respectively displaced by 90° in order to allocate a single cycle (360°) of the high frequency current to four high frequency induction antenna elements, and they satisfy the relationship of 360°/4=90°. The current I and the induction electric field E are associated via Maxwell's equations shown in the following expressions (1) and (2) using the induction magnetic field H. In the following expressions (1) and (2), E, H and I represent the vectors of all the electric field, magnetic field and current of the high frequency induction antenna and the plasma, μ represents the magnetic permeability, and ε represents the permittivity.

[Expression 1 and 2]

$$\begin{matrix}∇ \times E = - μ \frac{\partial H}{\partial t} & ( 1 ) \\ ∇ \times H = ɛ \frac{\partial E}{\partial t} + I & ( 2 )\end{matrix}$$

On the right side of FIG. 3A is shown the relationship between phases of the currents. The direction of the induction electric field E during a certain time (t=t1) in the area surrounded by the high frequency induction antenna is shown on the left side of FIG. 3A via dotted lines and arrows. As can be seen from this direction, the distribution of the induction electric field E is axi-symmetric in the plane in which the antenna is arranged, that is, the plane created by the antennas. The direction of the induction electric field E when the phase of the current is further advanced by 90° (t=t2) than FIG. 3A is shown in FIG. 3B. The direction of the induction electric field E is rotated in the right direction for 90°. From FIGS. 3A and 3B, it is recognized that the high frequency induction antenna of the present invention creates an induction electric field E that rotates in the right direction, or clockwise, with respect to time. When electrons exist within the induction electric field E rotating in the right direction, the electrons are driven by the induction electric field E and rotate in the right direction. In that case, the rotation cycle of the electrons corresponds to the frequency of the high frequency current. However, through engineering efforts, it is possible to create an induction electric field E having a rotation cycle that differs from the frequency of the high frequency current, and at that time, the electrons are rotated by the same cycle as the rotation cycle of the induction electric field E, and not by the frequency of the high frequency current. As described, similar to normal ICP sources, the electrons are driven by the induction electric field E in the present invention. However, the present invention differs from normal ICP sources or helicon plasma sources in that the electrons are driven in a fixed direction (right direction in the drawing) regardless of the phase of the current I of the high frequency induction antenna, and there is no moment where the rotation is stopped.

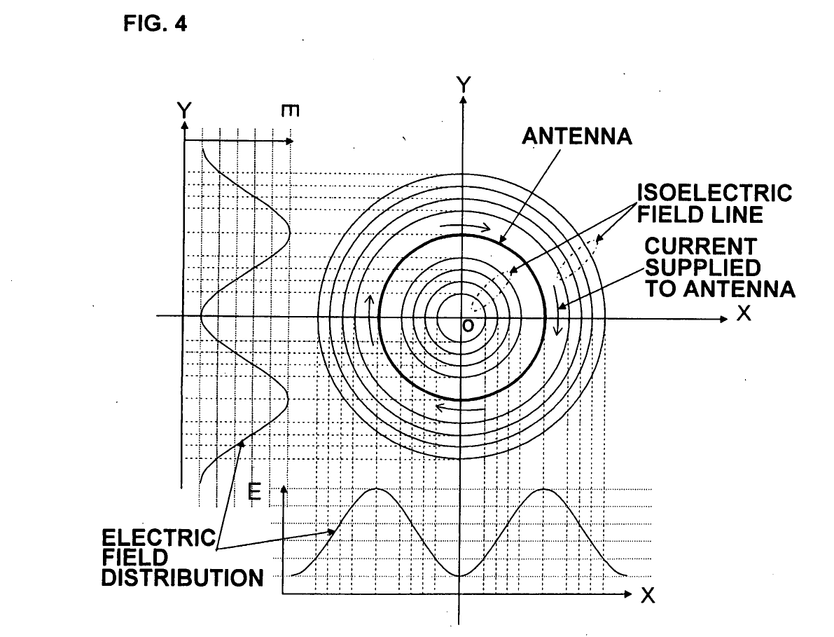

Now, we will describe what type of induction electric field E is generated in the plasma by the high frequency induction antenna according to the present invention. The description is based on induction electric field E, but a shown in expression (1), the induction electric field E and the induction magnetic field H are mutually exchangeable physical quantities, and are equivalent. First, FIG. 3 shows in frame format the distribution of the induction electric field E created via the prior art ICP source. According to the prior art ICP source, a current having a same phase is supplied to the antenna regardless of whether the antenna is circumferential and forms a circle or whether the antenna is divided into multiple elements, so that the induction electric field E created by the antenna becomes identical in the circumferential direction. In other words, as shown in FIG. 4, the maximum value of induction electric field E appears directly below the antenna, and a donut-shaped electric field distribution is formed that is attenuated toward the center of the antenna and the circumference of the antenna. The distribution is point-symmetric with respect to the center point O in the X-Y plane. Theoretically, the induction electric field E at the center point O of the antenna is E=0. This donut-shaped electric field distribution rotates in the right direction or the left direction according to the direction (half cycle) of the current. The rotating direction of the induction electric field E is reversed when the current becomes zero, and the induction electric field E becomes E=0 temporarily throughout the whole area. Such induction electric field E has been measured already as induction magnetic field H and confirmed (refer for example to non-patent document 2).

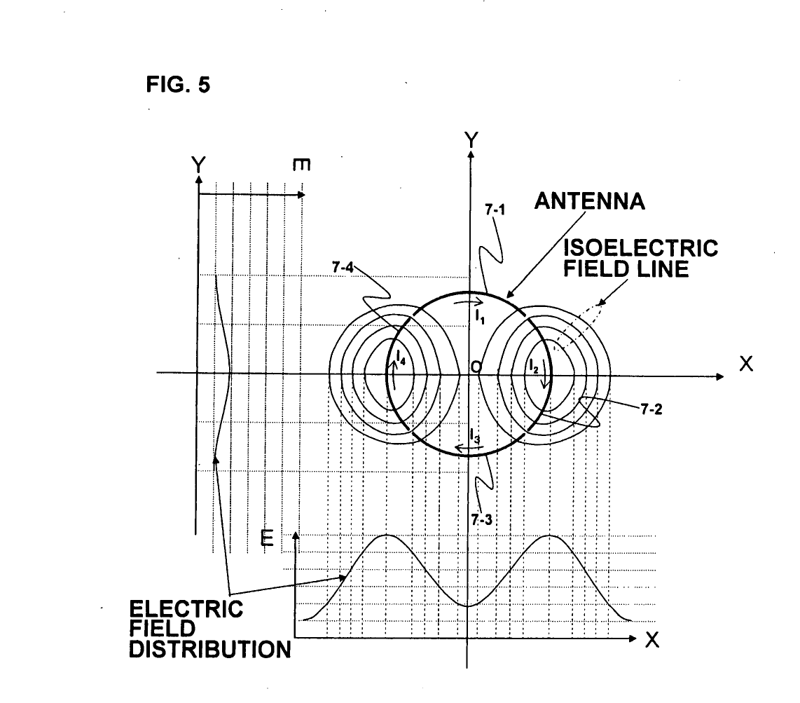

Next, we will describe the induction electric field E created by the antenna of the present invention. First, a current state as shown in FIG. 3A is considered. That is, a positive peak current flows to I₄, and an opposite peak current flows to I₂. Currents I₁ and I₃ are smaller. In this case, the maximum value of the induction electric field E appears below the antenna element 7-4 to which current I₄ flows and below the antenna element 7-2 to which current I₂ flows. Further, no strong induction electric field E appears below antenna elements 7-1 and 7-3 to which little current flows. This is shown in frame format in FIG. 5. Here, the state where two peaks appear on an X axis of an X-Y plane is illustrated. As can be seen in FIG. 5, the induction electric field E of the present invention has two large peaks on the circumference of the antenna, and is axi-symmetric on the X-Y plane (in the drawing, it is axi-symmetric with respect to axis Y). A distribution having a gentle peak appears on axis Y. The peak height of the gentle distribution is low, and the position appears on the center coordinate O. In other words, the induction electric field at center point O of the antenna is not E=0. As described, according to the arrangements of FIGS. 2A and 2B of the present invention, an induction electric field E that is totally different from that of the prior art ICP source and helicon plasma source is created, which rotates in a fixed direction (right direction in the drawing) regardless of the phase of the current I of the high frequency induction antenna. Further, as can be seen from FIGS. 3A and 3B, there is no moment when the currents I flowing to all the high frequency induction antenna elements simultaneously become I=0. Therefore, one of the characteristics of the present invention is that the rotating induction electric field E does not have a moment where E=0.

As described, the present invention generates an induction electric field distribution having a local peak, but the uniformity of the generated plasma is not deteriorated thereby. First, the induction electric field distribution on the X axis of FIG. 5 is determined by the induction magnetic field distribution generated by the antenna. That is, if the same current flows, the induction electric field distribution on the X axis of FIG. 4 and the induction electric field distribution on the X axis of FIG. 5 is equal in the sense that they are both symmetric induction electric fields having two peaks and a center disposed at center point O. Further, since the induction electric field of the present invention rotates via the same frequency as the high frequency current flowing in the antenna, so that by averaging the same by a single cycle of the high frequency current, it becomes possible to generate a point-symmetric induction electric field distribution with respect to the center point O on the X-Y plane. In other words, according to the present invention, a totally different induction electric field distribution from the prior art is created, but the preferable properties of the prior art ICP source is maintained, such as that the induction electric field distribution is determined by the structure of the antenna, and that a point-symmetric and circumferentially uniform plasma can be generated.

Here, through use of upper and lower magnetic field coils 81 and 82 and a yoke 83 illustrated in FIG. 1, it becomes possible to apply a magnetic field B having a magnetic field component perpendicular to the rotation plane of the induction electric field E. In the present invention, there are two conditions that must be satisfied by the magnetic field B. One is to apply a magnetic field B so that the direction of rotation of the rotating induction electric field E is constantly in the right direction with respect to the line of magnetic force of the magnetic field B. For example, according to the structure shown in FIGS. 2A and 2B, as have been described heretofore, the induction electric field E is rotated clockwise, or in the right direction, with respect to the sheet plane. In this case, components directed from the surface side toward the rear side of the sheet are required in the direction of the line of magnetic force. Thereby, the direction of rotation of the induction electric field E corresponds to the direction of rotation of Larmor motion of electrons. Further, this first condition can also be expressed to apply a magnetic field B in which the direction of rotation of the induction electric field E and the direction of rotation of the Larmor motion of electrons correspond.

The remaining condition is to apply a magnetic field B wherein E×B≠0 with respect to the induction electric field E. This condition of E×B≠0 must be satisfied at some area within the space in which plasma is to be generated, but it is not required to be satisfied in all the space in which plasma is to be generated. There are various methods for applying magnetic field, but unless a magnetic field having a locally complex structure is used, this condition of “E×B≠0” is included in the above-mentioned first condition. According to this condition “E×B≠0”, the electrons perform a rotary motion called a Larmor motion having the line of magnetic force as the guiding center. This Larmor motion is not a rotary motion by the rotating induction electric field mentioned earlier, but is a motion called an electric cyclotron motion. The rotating frequency thereof is called an electron cyclotron frequency ωc, and can be expressed by the following expression (3). In the following expression (3), q represents the elementary charge of electrons, B represents the magnetic field intensity, and me represents the mass of electrons. The characteristics of the electron cyclotron motion is that the frequency thereof is determined only by the magnetic field intensity.

[Expression 3]

$${ω}_{c} = \frac{qB}{{m}_{e}} \qquad ( 3 )$$

Now, when the rotation frequency f of the rotating induction electric field E is set to correspond to 2πf=ωc of the cyclotron frequency ωc, electron cyclotron resonance occurs, and the high frequency power supplied to the high frequency induction antenna is absorbed resonantly via the electrons, by which high density plasma can be generated. However, the condition that “the rotation frequency f of the rotating induction electric field E is set to correspond to the cyclotron frequency ωc” is required to be satisfied at some area in the space that plasma is to be generated, but it is not required to be satisfied throughout the whole space in which plasma is to be generated. The generation condition of ECR is represented by the following expression (4) as mentioned earlier.

[Expression 4]

2πf=ω_{c} (4)

The magnetic field B applied here can be a static magnetic field or a varying magnetic field. However, in the case of a varying magnetic field, the variation frequency fB must satisfy the relationship of 2πfB<<ωc with respect to the Larmor motion rotation frequency (electron cyclotron frequency ωc). What is meant by this relationship is that based on a single cycle of an electron performing electron cyclotron motion, the change of the varying magnetic field is sufficiently small, and that it can be regarded as a static magnetic field.

As described above, the plasma generating ability of electrons can be improved significantly by adopting a plasma heating method called electron cyclotron (ECR) heating. However, considering the desired plasma characteristics in industrial application, it is desirable to optimize the antenna structure so as to control the intensity and distribution of the induction electric field E, and to subject the intensity distribution of the magnetic field B to variable control, in order to create a space satisfying the conditions of the magnetic field B and the frequency at a necessary location within a necessary area, so as to control the plasma generation and the diffusion thereof. FIG. 1 shows an embodiment considering the same.

Further, the method for enabling ECR discharge in an ICP source according to the present invention does not depend on the frequency of the used high frequency or the magnetic field intensity, and is adoptable if the conditions described heretofore are satisfied. Of course, regarding engineering applications, there will be limitations on the used frequency and the magnetic field intensity based on actual limitations such as the size of the reactor of the plasma. For example, if the radius rL of the Larmor motion shown in the following expression is greater than the reactor in which the plasma is to be confined, the electrons will collide against the reactor wall without performing cyclic motion, and ECR phenomenon will not occur. In expression (5), v represents the velocity of electrons in the direction horizontal to the plane of the electric field shown in FIGS. 3A and 3B.

[Expression 5]

$$rL = \frac{v}{{ω}_{c}} \qquad ( 5 )$$

In this case, of course, it is necessary to increase the frequency of the used high frequency and to increase the magnetic field intensity so that ECR phenomenon occurs. However, the selection of the frequency and magnetic field intensity should be done freely based on the object, and the principle of the present invention itself will not be lost.

Now, the following four points are the necessary and sufficient conditions of the principle enabling ECR discharge to be performed using an ICP source. The first point is to create a distribution of induction electric field E that constantly rotates in the right direction with respect to the direction of the line of magnetic force of the magnetic field B applied to the space in which plasma is to be generated. The second point is to apply a magnetic field B satisfying E×B≠0 with respect to the distribution of induction electric field E that rotates in the right direction with respect to the magnetic field B and the direction of the line of magnetic force thereof. The third point is to match the rotation frequency f of the rotating induction electric field E and the electron cyclotron frequency ωc by the magnetic field B. The fourth point is that the change of magnetic field B is sufficiently small and that it can be regarded as a static magnetic field with respect to a single cycle of electrons performing electron cyclotron motion. The embodiment satisfying the above four points is illustrated in FIG. 1, but even if the embodiment of FIG. 1 is deformed, ECR discharge is enabled using the ICP source through any deformation as long as the necessary and sufficient conditions mentioned earlier are satisfied. In other words, it must be noted that even if the arrangement of the apparatus illustrated in FIG. 1 is deformed, the apparatus will still belong to the preferred embodiment of the present invention as long as the necessary and sufficient conditions are fulfilled. The deformation is merely a change in engineering design, and does not vary the physical principle illustrated in the present invention. The deformation example of FIG. 1 will be described below.

In FIG. 1, the vacuum reactor top member 12 is composed of a planar insulating material, and a high frequency induction antenna 7 is arranged above the same. What is meant by this arrangement is that a distribution of induction electric field E that constantly rotates in the right direction with respect to the direction of the line of magnetic force of the magnetic field B can be formed within the space in which plasma is to be generated, that is, the space between the vacuum reactor top member 12 and the object W to be processed. This is the content of the first point of the above-mentioned necessary and sufficient conditions. Therefore, the vacuum reactor top member 12 being a planar insulating material and the high frequency induction antenna 7 being disposed above the vacuum reactor top member 12 are not necessary arrangements according to the present invention. For example, the vacuum reactor top member 12 can be a rotated trapezoidal shape, a hollow semispherical shape or dome shape, or a cylindrical shape with a bottom. Further, the high frequency induction antenna can be positioned anywhere with respect to the vacuum reactor top member. Based on the principles disclosed in the present invention, any shape of the vacuum reactor top member 12 and the antenna position with respect to the top member are included in the preferred embodiment of the present invention as long as the above-mentioned necessary and sufficient conditions are satisfied.

However, from the viewpoint of industrial applicability, the shape of the vacuum reactor top member and the antenna position with respect to the top member have important meanings, since a uniform processing must be performed within the plane of the object W to be processed. In other words, the components of gas species constituting the plasma such as ions and radicals used for processing must form a uniform distribution on the plane of the object W to be processed.

Plasma is generated by the process gas being dissociated, excited and ionized by high energy electrons. The radicals and ions being generated at this time have strong electron energy dependency, and not only the amount of generation but the distribution of generation thereof differ between radicals and ions. Therefore, it is actually impossible to generate radicals and ions with identical distributions. Further, the generated radicals and ions spread via diffusion, but the diffusion coefficients vary between various types of radicals and ions. Especially, the diffusion coefficient of ions is normally greater by a few digits compared to the diffusion coefficient of neutral radicals. In other words, it is actually impossible to realize using diffusion to create a uniform distribution of radicals and ions simultaneously above the object W to be processed. Even further, upon generating plasma using process gas composed of molecules or formed by mixing a large variety of gases, multiple varieties of radicals and ions are generated, so it is even more impossible to realize uniform distribution of all radicals and ions. However, what is important in performing uniform processing is the variety of gas species contributing to advancing the plasma-applied process. For example, if the reaction is mainly progressed via a specific radical, it is important that the distribution of the specific radical becomes uniform. On the other hand, if the reaction is mainly progressed via ion sputtering, it is important that the distribution of the specific ion becomes uniform. Further, the reaction may be progressed by the competition of radicals and ions. In order to cope with such various processes, it is required that the process is advanced by realizing a more desirable uniformity by controlling the distribution and diffusion of the generated plasma.

The present invention provides two types of solutions for the above-mentioned demands. Since according to the present invention, the energy of electrons for generating plasma is determined by E×B, that is, the induction electric field E and the magnetic field B. The first solution relates to the induction electric field E, wherein the shape of the vacuum reactor top member 12 formed of insulating material and the position of the antenna with respect thereto are optimized per process. As mentioned earlier, according to the present invention, the distribution of the generated plasma is determined by the arrangement of the antenna, similar to normal ICP sources. This is because the strongest induction electric field E is formed near the antenna. Furthermore, the distribution of generated radicals and ions can be controlled by the spread of the space defined by the vacuum reactor top member, the object to be processed and the vacuum reactor. This is also closely related to the magnetic field B regarding the second solution, but here, the magnetic field will not be taken into consideration so as to simplify description.

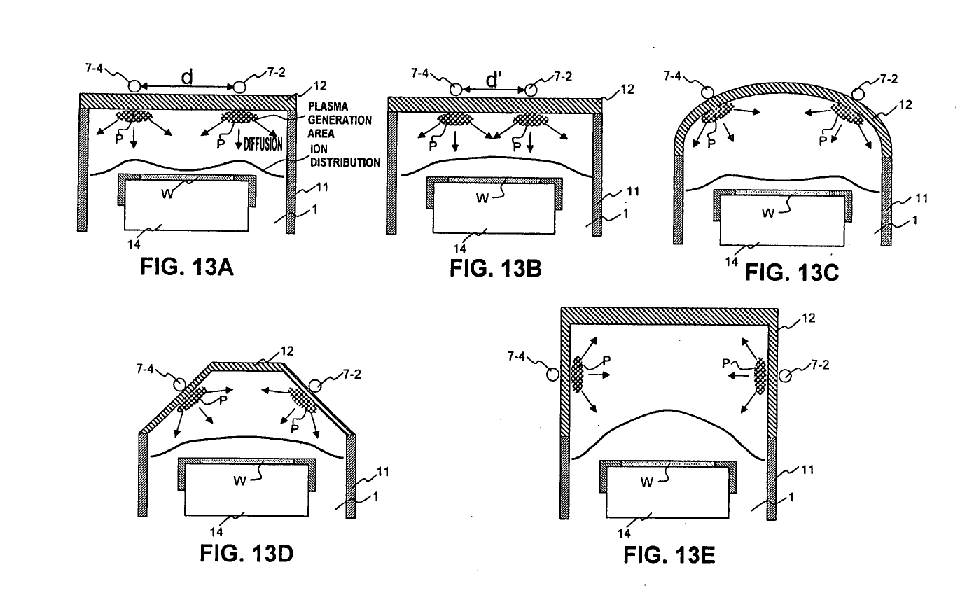

FIGS. 13A through 13E show in frame format the shapes of the distribution above the object W to be processed with respect to the four varieties of shapes of the vacuum reactor top member 12 composed of insulating material and the antenna position. In order to simplify the description, the distribution shows the distribution of ions. FIG. 13A shows a case where the vacuum reactor top member 12 formed of insulating material is plate-shape. The high frequency induction antenna elements 7 are disposed above the insulating vacuum reactor top member 12, and a generation space P of ions (plasma) appears immediately below the antennas. The ions generated at this time is diffused and spreads within the space surrounded by the vacuum reactor top member 12 and the vacuum reactor 11. Based on qualitative description, the direction of diffusion at this time is downwards. It is assumed that by such diffusion, an M-shaped ion distribution is formed above the object W to be processed. At this time, it is assumed that the distance d between antennas is set smaller as shown in d′ of FIG. 13B. By such change of antenna position, the ion diffusion is directed further toward the center area of the object W to be processed. Therefore, the ion distribution above the object W to be processed can be center-high. Although not shown, by widening the antenna distance, the M-shaped distribution of ions can be further enhanced. In other words, the change of antenna arrangement is very useful in controlling the distribution of ions. However, by merely changing the antenna arrangement, the ions and radicals other than the one considered in the above example is also subjected to the same change in distribution. This is because there is small change in the spread of plasma generating region with respect to the antenna, and the space formed by the vacuum reactor top member 12 formed of insulating material and the vacuum reactor 11 is the same.

Such control of distribution is enabled by changing the shape of the vacuum reactor top member 12 formed of insulating material. FIGS. 13C, 13D and 13E show in frame format the distribution of ions when the shape of the vacuum reactor top member is changed respectively to a hollow semispherical shape, a rotated trapezoidal shape having a space formed in the interior thereof, and a cylindrical body with a bottom. It can be recognized from the drawings that along with the change of shape of the vacuum reactor top member 12 formed of insulating material from FIG. 13A to FIG. 13C, FIG. 13D and FIG. 13E in the named order, the diffusion of ions toward the center area is increased. Therefore, by changing the shape from FIG. 13A to FIG. 13C, FIG. 13D and FIG. 13E in the named order, the center-high distribution of ions above the object W to be processed is enhanced further.

In the drawing, it is shown that the distributions of ions above the object W to be processed are the same shapes according to FIGS. 13B and 13D. This can be realized by appropriately designing the structure of the actual apparatus. However, the change of design from FIG. 13A to FIG. 13B and the change from FIG. 13 A to FIG. 13 D have conclusive differences. The difference is that the volume of the space defined by the vacuum reactor top member 12 formed of insulating material and the vacuum reactor 11 and the surface area thereof differ.

At first, the probability of ions vanishing within the space is extremely small, and the main cause of vanishing is the charge emission at the surface of the wall. In order for ions to vanish in the space, an extremely rare reaction such as colliding against two electrons at the same time (triple collision) is required. Further, there is a limitation that the collision of ions against the wall must be of equal quantity with electrons (quasi-neutrality condition of plasma). However, radicals are neutral excited species, and they lose their active energy easily by colliding with a single electron or with other molecules. The opposite case is also possible. Radicals also collide against walls and lose their excitation energy, but the flow-in thereof is unrelated to the quasi-neutrality condition of plasma, and is merely determined by the amount of diffusion to the wall. Of course, as mentioned earlier, the diffusion coefficients of ions and radicals differ greatly. In other words, by changing the volume of the space defined by the vacuum reactor top member 12 formed of insulating material and the vacuum reactor 11 and the surface area thereof, the level of generation area, diffusion and disappearance of radicals with respect to ions can be varied further. As described above, compared to the change from FIG. 13A to FIG. 13B, the change from FIG. 13A to FIG. 13D enables a more dynamic control of the distribution of ions and radicals.

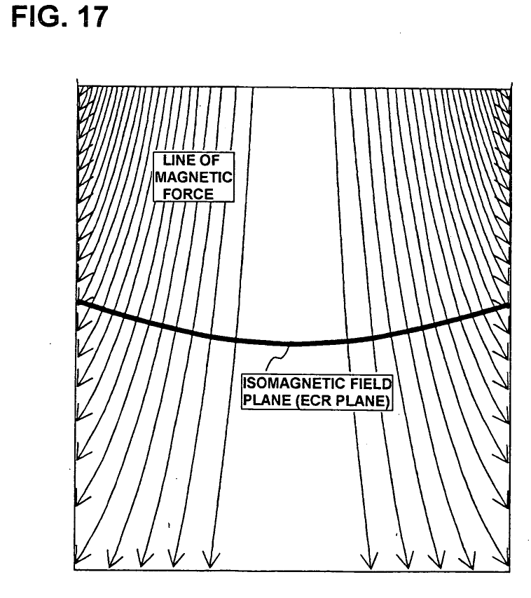

The second solution is related to the magnetic field B, so as to optimize the generation and diffusion of plasma by variably controlling the shape of the vacuum reactor top member 12 formed of insulating body and the magnetic field distribution thereof. According to the embodiment shown in FIG. 1, the intensity and distribution of the magnetic field is controlled by the current supplied to the upper and lower magnetic field coils 81 and 82 and the shape of the yoke 83. At this time, for example, it is possible to generate a magnetic field as shown in FIG. 17. The characteristic property of this magnetic field is that the direction of the line of magnetic force is downwards. Based on the direction of the line of magnetic force and the direction of the electric field shown in FIGS. 3A and 3B, the direction of rotation of the electric field shown in FIGS. 3A and 3B and the Larmor motion of the electrons rotate in the same right direction with respect to the direction of the line of magnetic force. In other words, the present magnetic field is an example in which the first and second conditions of the above-mentioned necessary and sufficient conditions are both satisfied.

An isomagnetic field plane is formed on a plane perpendicular to the line of magnetic force. There are a large number of isomagnetic field planes, one of which is shown as an example in FIG. 17. In the example, if the rotation cycle of the induction electric field distribution rotating in the fixed direction is 100 MHz, based on expression (3), a magnetic field intensity plane for causing ECR discharge is approximately 35.7 Gauss isomagnetic field plane. This is called an ECR plane. In the example, the ECR plane is convexed downward, but it can be planar or convexed upward. According to the present invention, it is necessary to create an ECR plane in the plasma generating area, but the shape of the ECR plane is optional. The ECR plane can be moved up and down by varying the currents supplied to the upper and lower magnetic field coils 81 and 82, and the planar shape can be convexed further downward, planar or convexed upward.

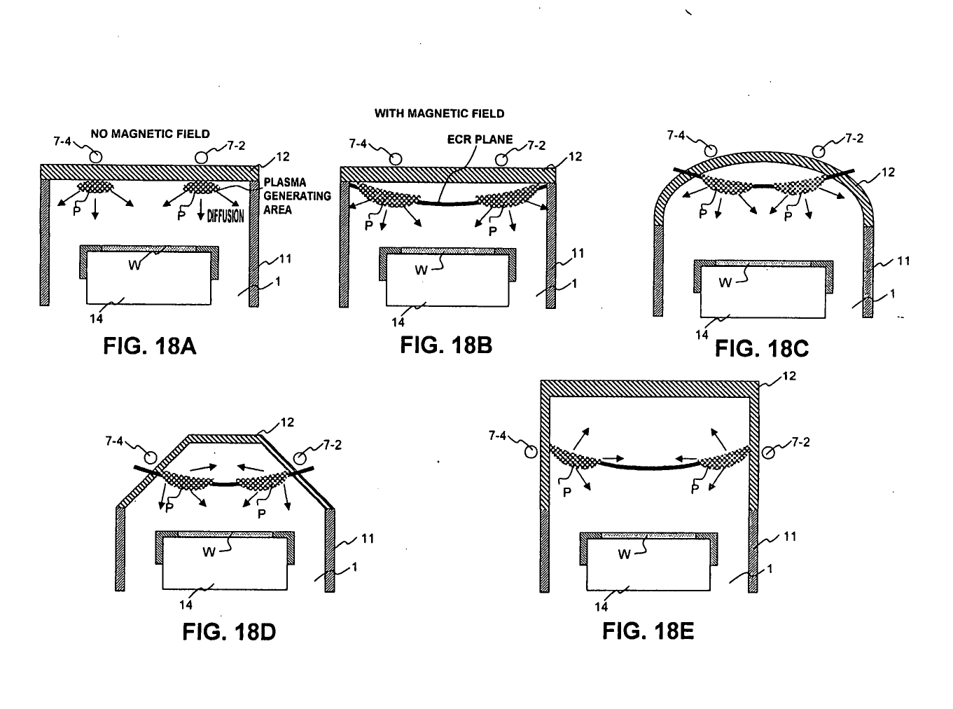

Next, the effect of combining the variation of the ECR plane and the shape of the vacuum reactor top member is described with reference to FIGS. 18A through 18E. FIG. 18A is identical to FIG. 13A, wherein the generation area of plasma (the area with the checked pattern) and the direction of diffusion thereof are illustrated in frame format when no magnetic field is generated. With respect to FIG. 13A, an example in which the ECR plane is formed is shown in FIG. 18B. The following points (1), (2) and (3) are important. (1) The plasma generating area via ECR exists along the ECR plane. By comparing the case where no magnetic field is formed with the case where the ECR plane is formed, it can be recognized qualitatively that the generation areas of ions and radicals in the plasma are varied. (2) The intensity of discharge is increased along with the size of the induction electric field E when no magnetic field is generated, but in the case of ECR discharge, it is increased along with the size of E×B. (3) Since according to ECR, the electrons resonantly absorb the energy of the electric field, so that even in the same induction electric field E, the ECR has an overwhelming discharge intensity compared to when no magnetic field is formed. The points (2) and (3) indicate in principle that the generation area of ions and radicals in the plasma are varied between the case where no magnetic field is generated and where an ECR plane is formed. Of course, according to the embodiment shown in FIG. 1, the planar shape of the ECR plane and the vertical position of the ECR plane with respect to the vacuum reactor top member can be varied greatly by changing the currents supplied to the upper and lower magnetic field coils 81 and 82 and the shape of the yoke 83, so that by comparing the case where no magnetic field is generated and the case where the ECR plane is formed, the generation areas of ions and radicals in the plasma can be varied significantly.

Further, when an ECR plane is formed, the state of diffusion varies compared to when there is no magnetic field. In other words, since the ions and electrons in the plasma are charged particles, they are easily diffused along the magnetic field, and are not easily diffused perpendicularly with respect to the magnetic field. Electrons are diffused along the line of magnetic force in a state where they are wound around the line of magnetic force via Larmor motion, and the ions are diffused in the same direction as the electrons according to the requirement of the quasi-neutrality of plasma. However, since radicals are neutral particles, the diffusion thereof is not affected by the magnetic field. In other words, it can be recognized that the formation of the ECR plane not only changes the area in which the ions and radicals are generated, but also influences the distribution shape of ions and radicals via diffusion. Thus, the magnetic field is an extremely efficient means for controlling the plasma generation distribution and diffusion. FIGS. 18C, 18D and 18E are views corresponding to FIGS. 13C, 13D and 13E, showing in frame format the generation area of plasma when the shape of the vacuum reactor top member 12 formed of insulating material is changed to a hollow semispherical shape, a rotated trapezoidal shape with a space formed therein, and a cylindrical shape with a bottom. Of course, the sizes of the space defined by the respective vacuum reactor top member and the surface areas thereof differ, so the differences in diffusion and disappearance described with reference to FIGS. 13A through 13E are the same in principle.

There is one more thing that can be recognized from FIGS. 18A through 18E. That is, according to the present invention, there is no need for a vertically long vacuum reactor designed specifically for use of helicon waves, as typically disclosed in patent document 5. According to the present invention, a horizontally long vacuum reactor as shown in FIG. 18B or a vertically long vacuum reactor as shown in FIG. 18E can be selected arbitrarily. This is because in order to excite helicon waves, sufficiently long absorption length must be taken so as to absorb the propagated helicon waves sufficiently during propagation (the vacuum reactor must be long), whereas according to the present invention, the energy of the electric field is absorbed by the ECR plane, and so there is no need to provide a long absorption length. According to the present invention, the size of the space for absorbing the energy of induction electric field should be large enough so as to form the ECR plane (isomagnetics field plane and rotation plane of electrons). This is because the ECR plane is merely a resonant plane, and it is not waves that are propagated in a certain direction. This is the conclusive difference between the case where helicon waves are used and the case where an ECR plane is used, showing the reason why the present invention has sufficient usability compared to the case where the helicon plasma source is used.

As described, the present invention has three kinds of devices for generating, diffusing and extinguishing plasma, that are (1) the antenna structure, (2) the structure of the vacuum reactor top member 12 formed of insulating material, and (3) the magnetic field. These characteristic features were not easily obtained according to prior art plasma sources such as the ICP source, the ECR plasma source or the parallel plane plasma source. Especially, even after determining the apparatus structure such as the antenna structure and the shape of the vacuum reactor top member 12 formed of insulating material, the magnetic field can be changed by varying the currents supplied to the upper and lower magnetic field coils 81 and 82 so as to control the generation area of plasma and the diffusion thereof even more dynamically.

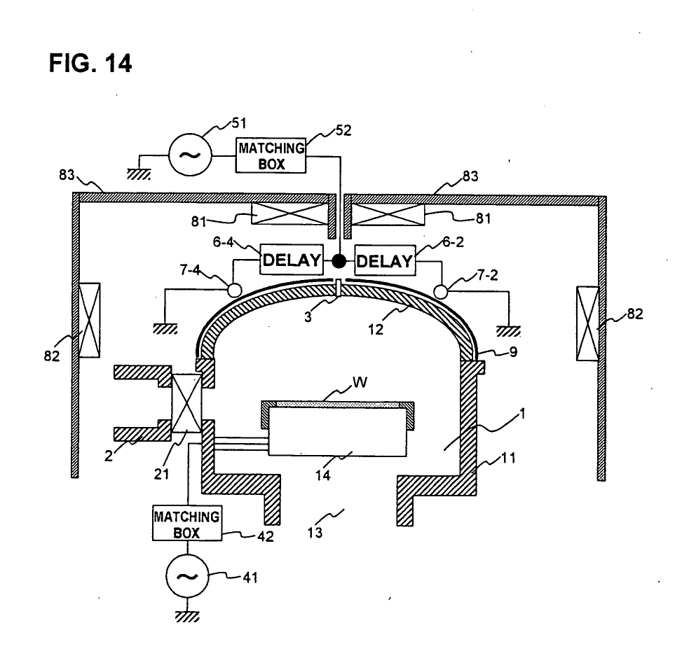

With reference to FIG. 14, a second embodiment of the shape of the vacuum processing chamber top member will be described. In FIG. 14, the structure other than the shape of the vacuum reactor top member 12 is substantially the same as that of the plasma processing apparatus according to FIG. 1, so the same components are denoted by the same reference numbers and the descriptions thereof are omitted. The vacuum processing chamber top member is composed of a planar (disk-shaped) insulating member, but in the present example, the vacuum processing chamber top member 12 formed of insulating material is a hollow semispherical shape or dome shape, which is fixed air-tightly to the top portion of the cylindrical vacuum reactor 11 as shown to define the vacuum processing chamber 1. According to this arrangement, a plasma generation area is formed on the ECR plane, as shown in FIG. 18C.

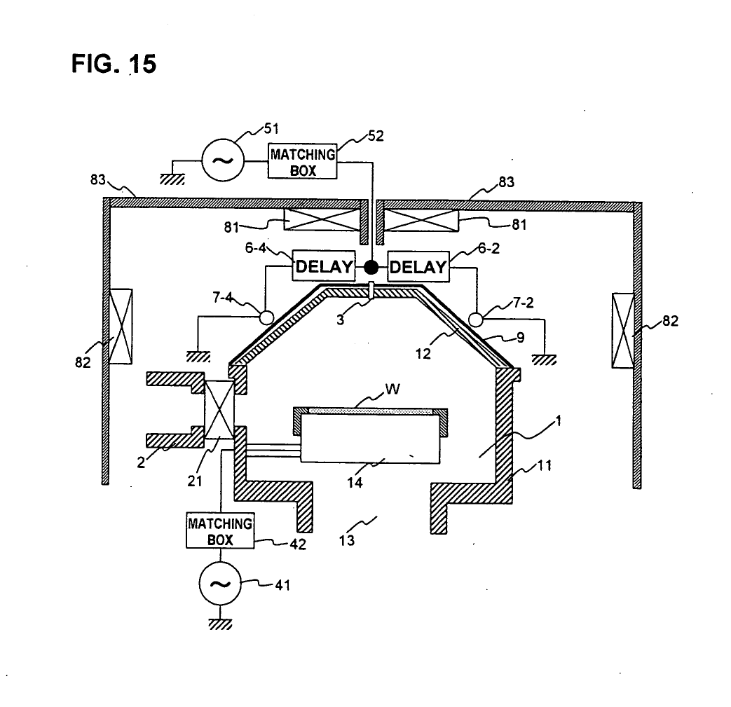

A third example of the shape of a vacuum processing chamber top member will be described with reference to FIG. 15. In FIG. 15, the structure other than the shape of the vacuum reactor top member 12 is substantially the same as that of the plasma processing apparatus according to FIG. 1, so the same components are denoted by the same reference numbers and the descriptions thereof are omitted. According to the present example, the vacuum processing chamber top member 12 composed of insulating material has a shape in which the top portion of a hollow cone-shape is removed to constitute a planar ceiling with a space formed therein, and as illustrated, it is fixed air-tightly to the top portion of the cylindrical vacuum reactor 11 to define the vacuum processing chamber 1. In the present specification, this shape of the vacuum reactor top member is called a rotated trapezoidal shape. According to this arrangement, as shown in FIG. 18D, a plasma generation area P is formed on the ECR plane.

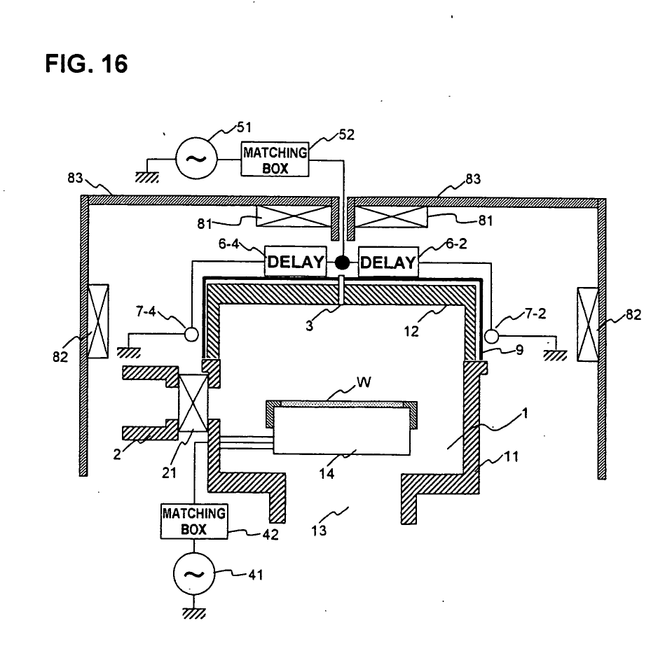

The fourth example of the shape of the vacuum processing chamber top member will be described with reference to FIG. 16. In FIG. 16, the structure other than the shape of the vacuum reactor top member 12 is substantially the same as that of the plasma processing apparatus according to FIG. 1, so the same components are denoted by the same reference numbers and the descriptions thereof are omitted. According to the present example, the vacuum processing chamber top member 12 composed of insulating material is cylindrically shaped with a bottom and having a space formed in the interior thereof, wherein the bottom portion is placed at the top as illustrated and fixed air-tightly to the top portion of the cylindrical vacuum reactor 11 to define the vacuum processing chamber 1. In the present specification, this shape of the vacuum reactor top member 12 is called a cylindrical shape with a bottom. According to this arrangement, as shown in FIG. 18E, a plasma generation area P is formed on the ECR plane.

The functions according to these deformation examples are the same as those of the embodiment illustrated in FIG. 1. The differences are that the ranges of distribution control of the ions and radicals in the plasma generated by the respective plasma sources (the generation area and the degree of diffusion and disappearance) differ. The selection of these plasma sources should be performed based on the type of process that the present invention is actually applied to.

The following is a description on the shape and the arrangement of the high frequency induction antenna. In FIG. 1 (FIGS. 2A and 2B), the high frequency induction antenna elements 7-1, 7-2, 7-3 and 7-4 divided into four parts are arranged on a single circumference. However, this arrangement that the elements are arranged “on a single circumference” is not a necessary condition for realizing the first content of the aforementioned necessary and sufficient conditions. For example, the first content of the aforementioned necessary and sufficient conditions can be realized by arranging the four parts of the high frequency induction antenna on inner and outer circumferences of two large and small circumferences of a planar insulating member 12, or by arranging the same vertically or obliquely. In other words, as long as the first content of the aforementioned necessary and sufficient conditions can be realized, the number of the circumferences or the arrangements thereof can be determined freely. Similar to the case of the planar vacuum reactor top member 12, even if the vacuum reactor top member 12 formed of insulating material is of rotated trapezoidal shape, hollow semispherical shape (dome shape) or cylindrical shape with a bottom, the high frequency induction antennas can be arranged on inner and outer circumferences thereof, or can be arranged vertically or obliquely. Moreover, it is also possible to arrange the divided parts of the antenna on three or more circumferences.

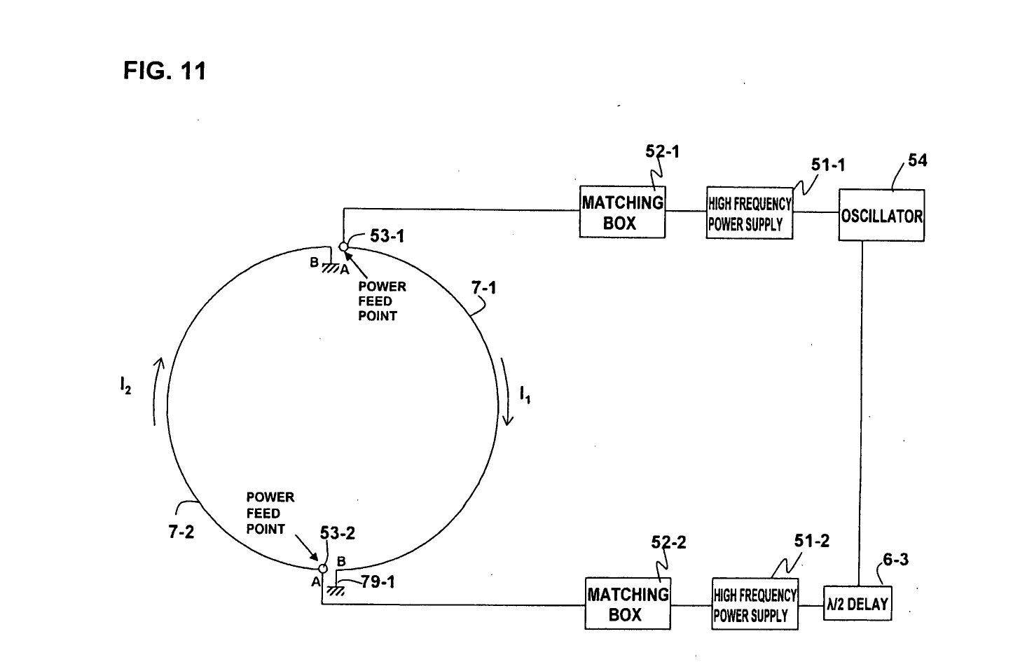

In FIG. 1 (FIGS. 2A and 2B), circular arc-shaped high frequency induction antenna elements 7-1, 7-2, 7-3 and 7-4 having a circle divided into four parts is arranged on a single circumference. This arrangement where the circle is “divided into four parts” is not a necessary arrangement for realizing the first content of the aforementioned necessary and sufficient conditions. The division number of the high frequency induction antenna can be an integer n satisfying n≧2. It is possible to constitute a high frequency induction antenna 7 having a single circumference using n-number of circular arc antennas (high frequency induction antenna elements). Further, according to FIG. 1, a method for forming an induction electric field E that rotates in the right direction with respect to the direction of the line of magnetic force through phase control of currents supplied to the high frequency antennas is illustrated, which is surely realizable when n≧3. The case where n=2 is special, meaning for example that a single circumference is formed using two semicircular antennas, and currents having a phase difference of (360°)/(two antennas)=(180°) are supplied to the respective antennas. In this case, it appears as though by simply supplying such currents, the induction electric field E may rotate in both right and left directions, and the first content of the aforementioned necessary and sufficient conditions cannot be satisfied. However, by applying a magnetic field satisfying the necessary and sufficient conditions of the present invention, the electrons rotate in the right direction spontaneously via Larmor motion, and as a result, the induction electric field Erotates in the right direction. Therefore, the division number of the high frequency induction antennas according to the present invention can be an integer n satisfying n≧2, as described. This feature is described in detail in FIG. 11.

In FIG. 1 (FIGS. 2A and 2B), the circular arc-shaped high frequency induction antenna elements 7-1, 7-2, 7-3 and 7-4 in which a circle is divided into four parts is arranged on a single circumference. This arrangement of antenna elements “on a circumference” is also not a necessary condition for realizing the first content of the aforementioned necessary and sufficient conditions. For example, even by arranging four linear-shaped high frequency induction antenna elements in a rectangle, the first content of the aforementioned necessary and sufficient conditions can be realized. Of course, it is possible to form a high frequency induction antenna 7 having an n-sided shape using n-number of linear high frequency induction antenna elements satisfying n≧2 (when n=2, the two elements should be opposed to one another with a certain distance therebetween).

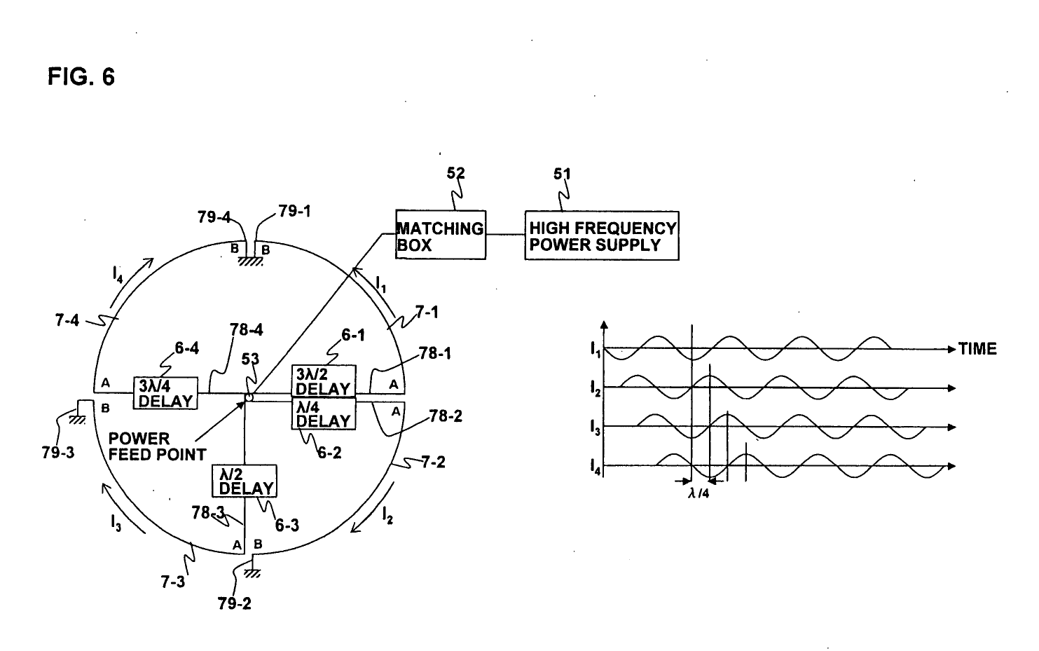

In FIG. 1 (FIGS. 2A and 2B), power feed ends A and earth ends B of the circular arc-shaped high frequency induction antenna elements 7-1, 7-2, 7-3 and 7-4 having divided a circle into four parts are arranged point-symmetrical on a single circumference in the order of ABABABAB. However, this arrangement that the “power feed ends and the earth ends are arranged in point symmetry” is also not a necessary arrangement for realizing the first content of the aforementioned necessary and sufficient conditions. The power feed ends A and the earth ends B can be arranged freely. The present embodiment corresponding to FIGS. 2A and 2B is illustrated in FIG. 6. FIG. 6 shows an example in which the positions of the power feed end A and the earth end B of the high frequency induction antenna element 7-1 are reversed, by which the direction of the high frequency current I₁ is reversed. However, in this case, the phase of the high frequency current I₁ supplied to the high frequency induction antenna element 7-1 can be reversed from the phase shown in FIGS. 2A and 2B (for example, delaying the same by 3λ/2), by which the rotating induction electric field E as shown in FIG. 5 can be realized. It can be recognized that the reversing of position of the power feed end A and the earth end B is equal to reversing the phase, that is, delaying the same by λ/2.

### Embodiment 2

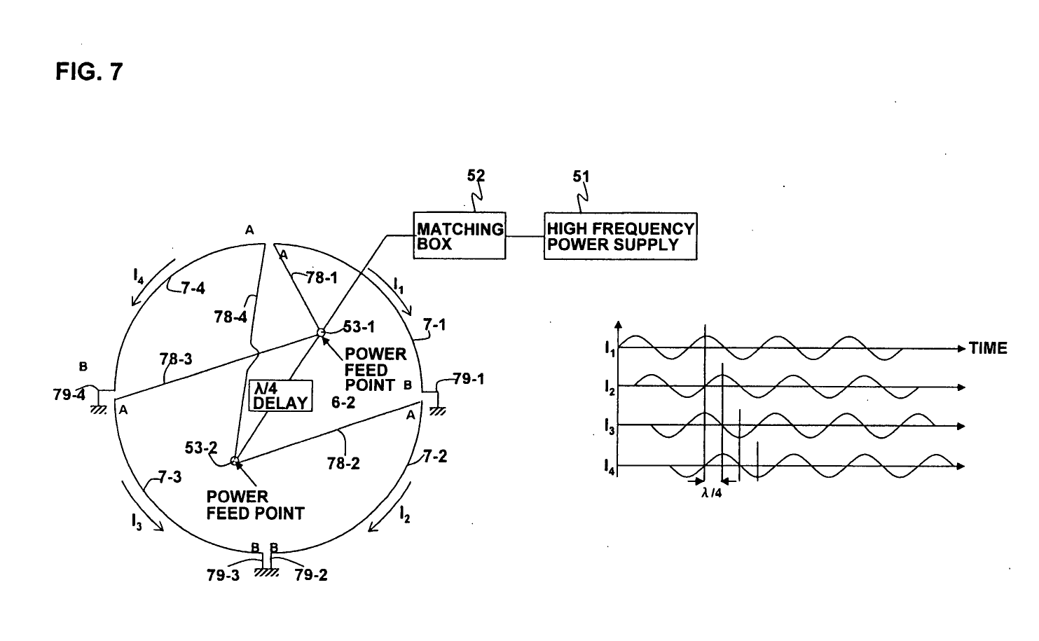

The above-mentioned feature can be utilized to simplify the arrangement of FIGS. 2A and 2B, which will be shown in FIG. 7. The arrangement of FIG. 7 utilizes the fact that in FIGS. 2A and 2B, I₁ and I₃, and I₂ and I₄ are respectively delayed by λ/2, in other words, are reversed, and in the present embodiment, the current having the same phase is supplied to I₁ and I₃, and I₂ and I₄, but the arrangements of power feed ends A and earth ends B of I₃ and I₄ are reversed. Even further, since a λ/4 delay 6-2 is disposed between I₁ and I₃, and I₂ and I₄, a rotating induction electric field E (as shown in FIG. 5) similar to FIGS. 2A and 2B can be formed. As described, the combination of the arrangement of the high frequency induction antenna and the phase control can create a large variation. However, such variations are merely issues of engineering designs, and as long as the arrangement satisfies the first content of the aforementioned necessary and sufficient conditions, it will constitute an embodiment of the present invention.

### Embodiment 3

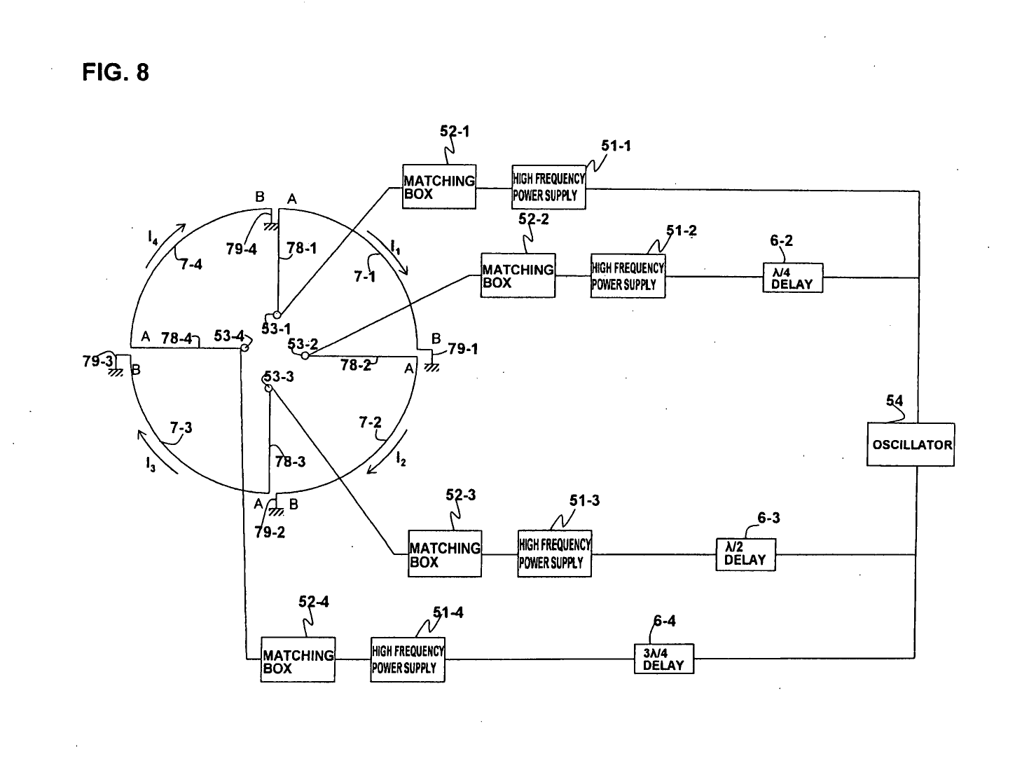

In FIG. 1, phase delay circuits are disposed between the matching box disposed on the power supply output portion and the high frequency induction antenna elements 7-1 through 7-4. However, this arrangement where “phase delay circuits are disposed between the matching box and the high frequency induction antenna elements 7-1 through 7-4” is not a necessary arrangement for realizing the first content of the aforementioned necessary and sufficient conditions. In order to satisfy the first content of the necessary and sufficient conditions, current should simply be supplied to the high frequency induction antenna so as to form a rotating induction electric field E as shown in FIG. 5. Now, an embodiment where the rotating induction electric field E as shown in FIG. 5 is formed as illustrated in FIGS. 2A and 2B but with a different arrangement is shown in FIG. 8. The arrangement of FIG. 8 supplies currents to high frequency induction antenna elements 7-1 through 7-4 from the same number of high frequency power supplies 51-1 through 51-4 as the number of high frequency induction antenna elements 7-1 through 7-4, wherein the output of a single oscillator is connected to high frequency power supplies 51-1 through 51-4 and matching boxes 52-1 through 52-4 respectively via no delay means, via λ/4 delay means 6-2, λ/2 delay means 6-3 and 3λ/4 delay means 6-4, so as to perform necessary phase delays. The increase of high frequency power supplies 51 leads to increase of matching circuits 53, but the quantity of electric power of a single high frequency power supply can be reduced, and the reliability of the high frequency power supplies can be improved. Further, by fine-adjusting the power supplied to the respective antennas, it becomes possible to control the uniformity of plasma in the circumference direction.

### Embodiment 4

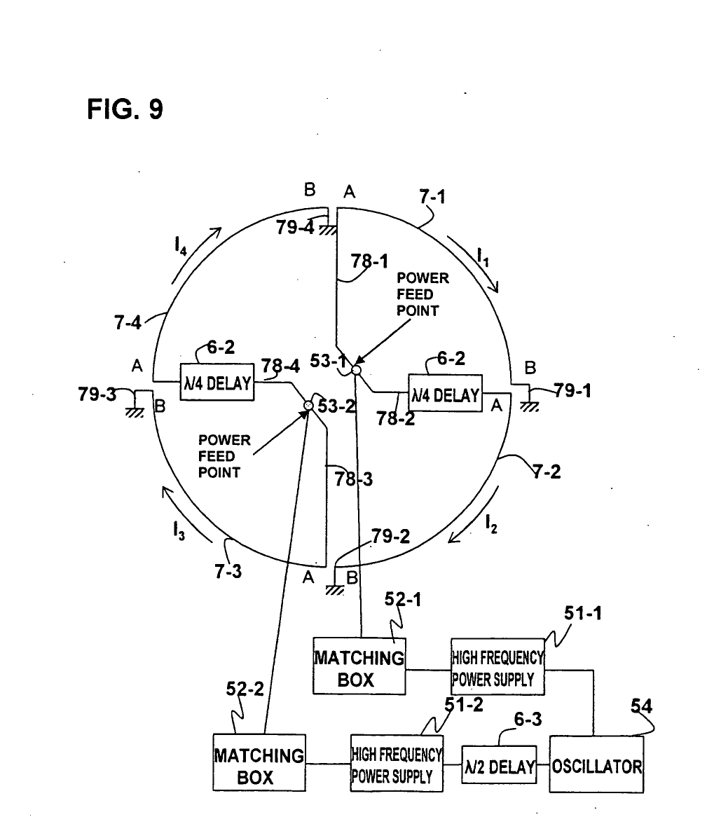

The variation of the power supply arrangement and high frequency induction antenna arrangement is not restricted to such example. For example, the application of the arrangements illustrated in FIGS. 2A and 2B and FIG. 8 enable to form a rotating induction electric field E as shown in FIG. 5 similar to the case of FIGS. 2A and 2B, but yet another arrangement can be adopted. This embodiment is shown in FIG. 9. According to the embodiment of FIG. 9, high frequency waves having a mutual λ/2 delay are output from two high frequency power supplies, a high frequency power supply 51-1 connected to an oscillator 54 and a high frequency power supply 51-2 connected thereto via a λ/2 delay means 6-3, to power feed points 53-1 and 53-2, and λ/4 delay means 6-2 are further disposed between the output of power feed points and the high frequency induction antenna elements 7-2 and 7-4 to perform necessary delays.

### Embodiment 5

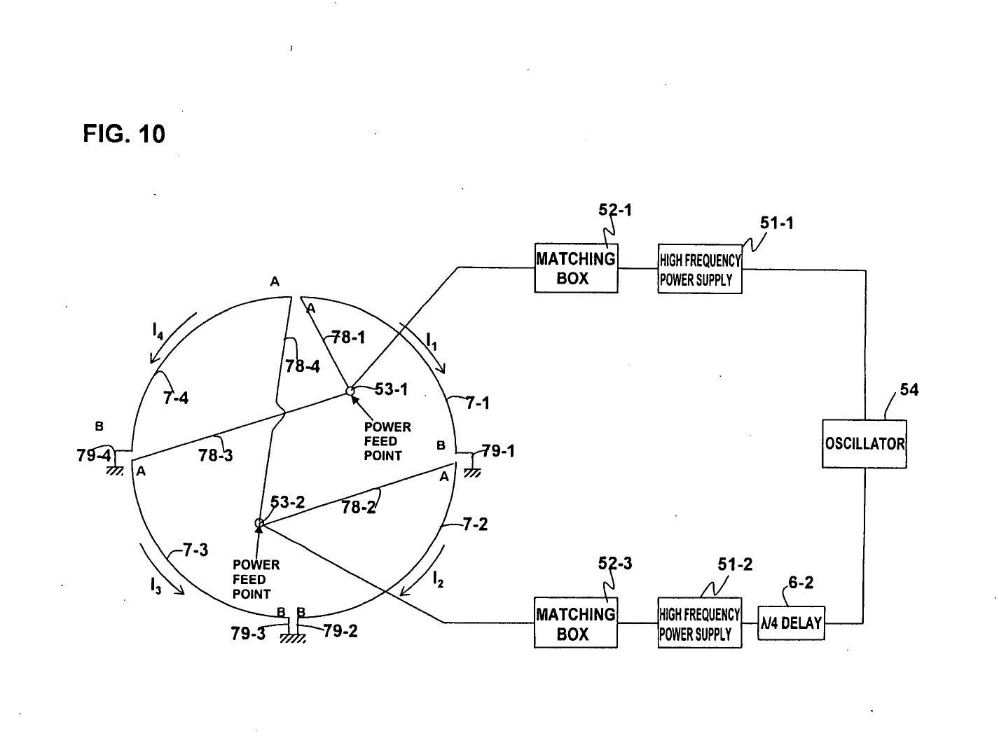

The next embodiment illustrated in FIG. 10 combines the embodiments of FIG. 9and FIG. 7. In FIG. 10, two high frequency power supplies 51-1 and 51-2 connected to the same oscillator 54 as FIG. 9 are used, but a λ/4 delay means 6-2 is inserted between the output of the oscillator 54 and one of the high frequency power supplies 51-3 so as to displace the phase by λ/4, and the power feed ends A and earth ends B of high frequency induction antenna elements 7-1 and 7-2 are positioned similarly as FIG. 9 but the power feed ends A and earth ends B of the high frequency induction antenna elements 7-3 and 7-4 are disposed in opposite directions (reversed) from high frequency induction antenna elements 7-1 and 7-2 as shown in FIG. 7. If the reference of phase of this output is the phase of I₁, the currents of I₁ and I₃ are of the same phase, but since the direction of I₃ (the power feed end A and earth end B) is reversed with respect to FIGS. 2A and 2B, the induction electric field E formed by I₁ and I₃ becomes the same as FIGS. 2A and 2B. Furthermore, I₂ and I₄ has a λ/4 phase delay compared to I₁ and the phases of the currents of I₂ and I₄ are the same, but since the direction of I₄ (the power feed end A and earth end B) is reversed with respect to FIGS. 2A and 2B, the induction electric field E formed by I₂ and I₄ becomes the same as FIGS. 2A and 2B. As a result, the embodiment illustrated in FIG. 10 has an arrangement that differs from FIGS. 2A and 2B, but forms the same induction electric field E as FIGS. 2A and 2B.

In other words, the present embodiment relates to a plasma processing apparatus comprising a vacuum reactor constituting a vacuum processing chamber for housing a sample, a gas supply port for introducing a processing gas into the vacuum processing chamber, a high frequency induction antenna disposed outside the vacuum processing chamber, a magnetic field coil for forming a magnetic field within the vacuum processing chamber, a plasma generating high frequency power supply for supplying high frequency current to the high frequency induction antenna, a power supply for supplying power to the magnetic field coil having high frequency current supplied to the high frequency induction antenna and a power supply for supplying power to the magnetic field coil, wherein high frequency power is supplied to the high frequency induction antenna from the high frequency power supply so as to turn the gas supplied into the vacuum processing chamber into plasma for subjecting the sample to plasma processing, characterized in that the high frequency induction antenna is divided into s-number (s being a positive even number) of high frequency induction antenna elements, the respective divided high frequency induction antenna elements being arranged in tandem on a circumference, the tandemly arranged high frequency induction antenna elements receiving supply of high frequency currents that are respectively delayed by λ(wavelength of high frequency power supply)/s in advance by s/2 number of high frequency power supplies sequentially in order from the first high frequency induction antenna element to the s/2^{nd} high frequency induction antenna element, the s/2+1^{st} high frequency induction antenna element to the s^{th} high frequency induction antenna element sequentially receiving supply of high frequency currents with the same phases as the first to s/2^{nd} high frequency induction antenna elements opposed thereto, the high frequency induction antenna elements being arranged so that the direction of currents supplied to the high frequency induction antenna elements is reversed, by which an electric field rotating in a fixed direction is formed to subject the sample to plasma processing, according to which the plasma for subjecting the sample to plasma processing is generated by forming an electric field rotating in a certain direction by supplying currents that are sequentially delayed in the right direction with respect to the direction of the line of magnetic force of the magnetic field formed by supplying power to the magnetic field coils.

As described, though the arrangements disclosed in FIGS. 2A and 2B, FIG. 6, FIG. 7, FIG. 8, FIG. 9 and FIG. 10 all differ, they all form the same induction electric field distribution E rotating in the right direction with respect to the line of magnetic force, as shown in FIG. 5. They are all variations satisfying the first content of the aforementioned necessary and sufficient conditions.

### Embodiment 6

As described, when the division number n of the high frequency induction antenna is n=2, the induction electric field E formed via the high frequency induction antenna rotates in the right direction with respect to the direction of the line of magnetic force by applying a magnetic field B satisfying the second content of the aforementioned necessary and sufficient conditions. According to this embodiment, high frequency waves having λ/2 phase differences are supplied to the two high frequency induction antenna elements. The basic arrangement of the present embodiment is shown in FIG. 11. According to the arrangement of FIG. 11, the power feed end A and earth end B of the antenna element 7-1 and the power feed end A and earth end B of the antenna element 7-2 are arranged in point symmetry in the circumference direction in the order of ABAB, and at the same time, one of the two outputs of the oscillator 54 is connected via the high frequency power supply 51-1 and the matching box 52-1 to a power feed point 53-1 of the power feed end A of the high frequency induction antenna element 7-1, and the other is connected via a λ/2 delay means 6-3, a high frequency power supply 51-2 and a matching box 52-2 to a power feed point 53-2 of the power feed end A of the high frequency induction antenna element 7-2.

Therefore, as shown in FIG. 11, the direction of the currents of the respective high frequency induction antenna elements is as shown by the arrow of I₁ and I₂. However, currents having reversed phases (having a λ/2 phase displacement) are supplied to the high frequency induction antenna elements 7-1 and 7-2, so as a result, the high frequency currents supplied to the high frequency induction antenna elements 7-1 and 7-2 are directed either upward or downward with respect to the drawing per half-cycle of the phase. Therefore, the induction electric field E formed in FIG. 11 has two peaks similar to FIG. 5. However, simply according to this arrangement, the electrons driven by the induction electric field E are capable of rotating both in the right direction and the left direction. By applying a magnetic field B (magnetic field having lines of magnetic force directed from the front surface to the rear surface of the sheet surface) that satisfies the aforementioned necessary and sufficient conditions, the electrons rotating in the right direction resonantly receive high frequency energy via ECR phenomenon and electron avalanche occurs highly efficiently, but the electrons rotating in the left direction cannot resonantly receive high frequency energy, so the ionization efficiency thereof is not good. As a result, the generation of plasma is mainly caused by the electrons rotating in the right direction, and electrons receiving high frequency energy efficiently and are accelerated to high speed will remain. At this time, the main current components in the plasma are composed of low-speed electrons rotating in the left direction and high-speed electrons rotating in the right direction, and of course, the electrons rotating in the right direction having reached high speed will become dominant, and the induction electric field E will rotate in the right direction, as can be recognized from expressions (1) and (2). This is similar to the prior art ECR plasma source using microwaves, UHF or VHF in which ECR discharge is caused even through the electric field is not rotated in a specific direction.

### Embodiment 7

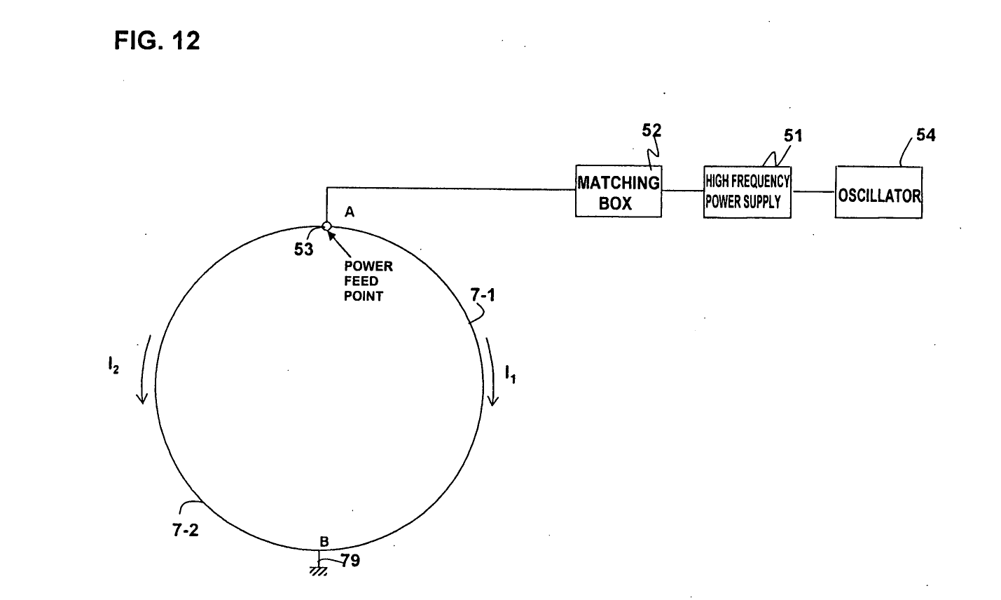

By adding the effect of FIG. 6 (or FIG. 7 or FIG. 10) to the arrangement of FIG. 11, as illustrated in FIG. 12, the ECR phenomenon can be caused via a simple arrangement. In FIG. 12, there is no supply of high frequency waves having reversed phases, and high frequencies of identical phases are supplied to the respective high frequency induction antenna elements, but the direction of currents are reversed by equalizing the power feed end A and earth end B of the respective high frequency induction antenna elements, according to which the same effect as FIG. 11 can be obtained. However, when the division number n of the high frequency induction antenna is n=2, there is a case where the currents flowing to the two high frequency induction antenna elements become zero simultaneously, so that exceptionally, there occurs a moment where the induction electric field E becomes E=0. When the division number n of the high frequency induction antenna is n≧3, current is supplied constantly to two or more high frequency induction antenna elements, so that there is no moment where the induction electric field E becomes E=0, as can be recognized clearly by creating drawings corresponding to FIGS. 3A and 3B for the respective cases.

For example, patent document 6 discloses at least three linear conductors arranged radially and at even intervals from the center of the antenna, wherein each linear conductor has one end earthed and the other end connected to an RF high frequency power supply. FIGS. 3(C) and (E) of patent document 6 discloses an arrangement where (a) the antenna is disposed in vacuum, (b) the antenna is composed of linear conductors, (c) the linear conductors are covered with insulating material, and (d) a magnetic field is applied thereto. These arrangements are very similar to the arrangement of FIG. 12 of the present invention where n=2. The object of the arrangement of patent document 6 is to supply a large electric power stably to the antenna disposed in vacuum to generate high density plasma and to control the diffusion thereof via a magnetic field so as to obtain a uniform distribution. However, the disclosed arrangement has a fatal defection compared to the present invention. The basic cause is that the antenna is introduced in vacuum. As disclosed in the document, the introduction of conductor antenna in vacuum makes it difficult to generate stable plasma due to abnormal discharge and the like. This is a fact also disclosed in non-patent document 3. Therefore, according to the invention disclosed in patent document 6, the antenna is composed of a linear conductor covered with insulating material to be insulated from plasma stably. However, the antenna is not only inductively coupled with plasma but also capacitively coupled therewith. In other words, the antenna conductor and the plasma are connected via electrostatic capacitance of the insulating cover, wherein a self bias voltage by high frequency voltage occurs to the plasma-side surface of the insulating cover, and the surface of the insulating cover is constantly sputtered via plasma ions. Thereby, a problem occurs. At first, when the insulating cover is sputtered, the semiconductor wafer subjected to plasma processing is contaminated by the material substance of the insulating cover, or the insulating cover causes particles via sputtering that stick to the surface of the semiconductor wafer and hinders normal plasma processing. The next problem is that the insulating cover is thinned by the elapse of time, and along with the increase of electrostatic capacitance of the insulating cover portion, the capacitive coupling of the antenna conductor and the plasma becomes strong along with the increase of electrostatic capacity of the insulating cover. With respect thereto, at first, the capacitive coupling causes the property of the generated plasma to vary with time, so that plasma having a fixed property cannot be generated. In other words, the plasma property changes with time. When the insulating cover is further thinned and capacitive coupling becomes stronger, a higher self bias voltage occurs, by which the insulating cover is consumed at an accelerated rate and the generation of particles and contamination is also accelerated. Finally, the weakest portion of the insulating cover breaks and the antenna conductor is directly exposed to plasma, by which an abnormal discharge occurs and no more plasma processing can be performed. Of course, the life of the antenna is limited. In other words, the arrangement of patent document 6 is not suited for industrial application. The disclosed apparatus may work in the beginning, but after a while, the property is deteriorated and the antenna must be replaced as consumable component, so the apparatus takes up much time and cost. On the other hand, according to the arrangement of the present invention, the antenna is disposed on the atmospheric side of the insulating top member 12, and the lifetime thereof is semi permanent, neither taking up time nor cost as consumable component. Further as shown in FIG. 1, there is a faraday shield between the antenna and the plasma, shielding the capacitive coupling of antenna and plasma. Therefore, the insulating top member 12 will not be sputtered via ions causing contamination of semiconductor wafer and particles, and will not be thinned via sputtering. Further, the difference between the present invention and the invention disclosed in patent document 6 is that the invention of patent document 6 is neither aimed at creating a rotating induction electric field nor causing ECR by the rotating induction electric field and magnetic field.

In FIG. 1, the two electromagnets, the upper coil 81 and the lower coil 82, and the yoke 83 are illustrated as components of the magnetic field. However, the necessary conditions of the present invention are to realize a magnetic field satisfying the aforementioned necessary and sufficient conditions, and therefore, the yoke 83 and the two electromagnets are not necessary components. For example, the upper coil 81 (or the lower coil 82) alone is enough as long as the necessary and sufficient conditions are fulfilled. The means for generating a magnetic field can be an electromagnet, a stationary magnet, or a combination of electromagnet and stationary magnet.

FIG. 1 shows a faraday shield 9. Intrinsically, faraday shields have a function to suppress capacitive coupling of the plasma and the antenna irradiating high frequency, so they cannot be applied to capacitively-coupled ECR plasma sources (for example, refer to patent document 5). In the present invention, however, similar to normal ICP sources, faraday shields can be applied. However, the “faraday shield” is not a necessary arrangement according to the present invention. It is not related to the aforementioned necessary and sufficient conditions. However, similar to normal ICP sources, the faraday shield is effective when considering industrial applicability. The faraday shield functions to block capacitive coupling of antenna and plasma without affecting the inductive magnetic field H irradiated from the antenna (that is, the induction electric field E). In order to complete the blocking effect further, it is preferable that the faraday shield is earthed. Normally in ICP sources, when the capacitive coupling is blocked as above, the igniting property of plasma is further deteriorated. However, according to the present invention, highly effective ECR heating via the induction electric field E caused by inductive coupling is used, so that an advantageous igniting property can be obtained even by shielding the capacitive coupling completely. However, due to various reasons, it is possible to connect an electric circuit to the faraday shield and to control the high frequency voltage generated to the faraday shield to 0 V or greater than 0 V.

FIG. 1 includes the gas supply port 3, the gate valve 21 and the wafer bias (bias power supply 41 and matching box 42) other than the components mentioned heretofore, but they are not related to the aforementioned necessary and sufficient conditions, so they are not necessary components of the present invention. The gas supply port is required to generate plasma but the position thereof can be on the side wall of the vacuum reactor 11 or on the electrode 14 for mounting the wafer W. Further, the gas can be injected via a plane or via points. The gate valve 21 is illustrated merely for the aim to transfer wafers in industrial application. Further, in the industrial application of the plasma processing apparatus, the wafer bias (bias power supply 41 and matching box 42) is not a necessity, and it is not indispensable when considering the industrial applicability of the present invention.

According to the present invention, the induction electric field E formed via the high frequency induction antenna rotates in the right direction with respect to the direction of the line of magnetic force of the magnetic field. The shape of the rotation plane is determined by the structure of the high frequency induction antenna, and can be circular or oval. Therefore, a center axis of rotation always exists. In industrial application, the magnetic field B, the object to be processed (such as circular wafers and rectangular glass substrates), the vacuum reactor, the gas injection port, the electrode on which the object to be processed is placed, and the evacuation port have center axes. According to the present invention, however, there is no need for the center axes to correspond, and they are not necessary conditions, since they are not related to the aforementioned necessary and sufficient conditions. However, when the uniformity of processing of the surface of the object to be processed (such as etching rate, deposition rate, or profile) becomes an issue, the center axes should preferably correspond.

As described, since according to the present invention a high frequency induction magnetic field for driving currents is constantly formed in the processing chamber, it is possible to improve the ignition property of plasma and to obtain high density plasma. Further according to the present invention, the length of the high frequency induction antenna can be controlled so as to correspond to demands for larger diameters, and to improve the uniformity of plasma in the circumferential direction.

The structure of the high frequency induction antenna from embodiments 1 through 7 can be applied to any shape of the second to fourth vacuum reactor top members 12.

Now, anther embodiment of the present invention will be described. According to the following embodiment of the present invention, multiple sets of high frequency induction antennas composed of a plurality of high frequency induction antenna elements are provided. Here, the number of sets of antennas composed of a plurality of high frequency induction antenna elements constituting a rotating induction electric field E is referred to as m. In the present invention, m can be any natural number. In other words, the antenna divided in to multiple parts can be disposed not only on two circumferences but on three or more circumferences. FIGS. 1, 2, 6 through 12 and 14 through 16 all illustrate cases where m=1. The number of m should be selected based on the object. The number of m should be determined according to industrial application, such as the necessary area of plasma, the area of the object to be processed, or the required level of plasma uniformity. There is a conclusive difference between the case where m equals 1 and where m equals 2 or greater. As described in detail later, when m equals 2, a tuning knob for controlling the generation distribution of plasma by controlling the level of currents supplied to the respective sets of antenna is increased. The case where m equals 3 or greater becomes too complex, so the case where m=2 will now be described.

### Embodiment 8

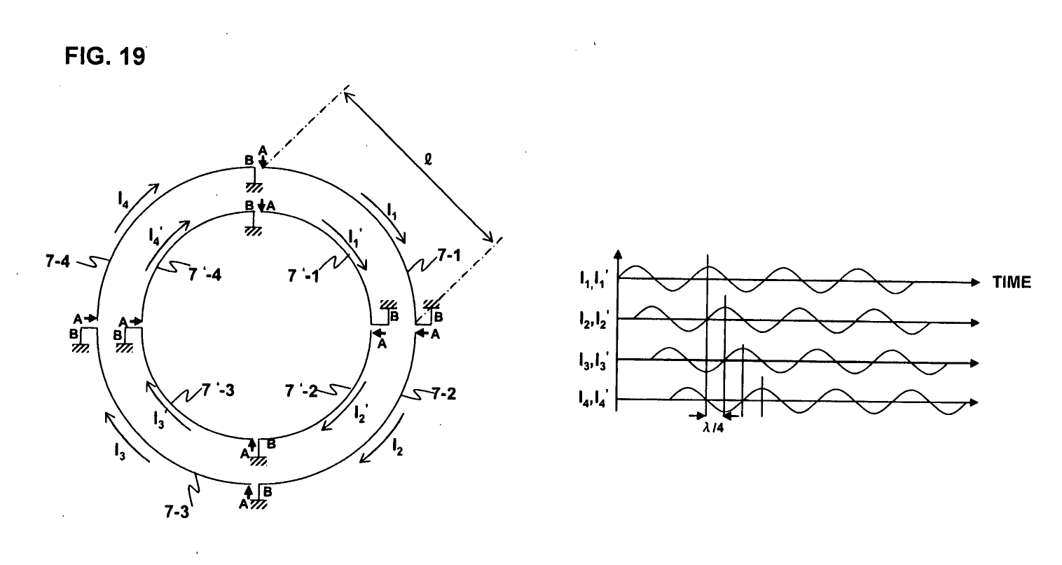

Embodiment 8 will now be described with reference to FIG. 19. FIG. 19 illustrates a case where the arrangement of FIGS. 2A and 2B or FIG. 8 (m=1) is expanded to m=2 (multiple sets) The high frequency power supply, the matching box, the current delay circuit and the power feed lines are omitted from the drawing for sake of simplification, and only the power feed ends A (arrows) and earth ends B of the high frequency induction antenna elements are illustrated. FIG. 19 includes antenna elements 7′-1, 7′-2, 7′-3 and 7′-4 disposed as pairs on the inner sides of high frequency induction antenna elements 7-1, 7-2, 7-3 and 7-4 illustrated in FIGS. 2A and 2B or FIG. 8. Hereinafter, the high frequency induction antenna elements 7-1, 7-2, 7-3 and 7-4 are referred to as outer antenna 7, and the high frequency induction antenna elements 7′-1, 7′-2, 7′-3 and 7′-4 are referred to as inner antenna 7′. In order to generate plasma having high uniformity, the outer antenna 7 and the inner antenna 7′ must be arranged concentrically. According to this arrangement, for example, the phase angles in the circumferential direction of the power feed ends A and the earth ends B of the high frequency induction antenna element 7-1 and the corresponding antenna element 7′-1 are the same. In this case, as shown in the right side of FIG. 19, currents having a same phase are supplied as I₁ and I₁′, and the phases of I₂ and I₂′, I₃ and I₃′ and I₄ and I₄′ are each sequentially varied by λ/4, respectively. In this example, the sum of the induction electric field (induction magnetic field) created by currents I₁ and I₁′ becomes greatest, and the transfer efficiency of power from the antenna to the plasma becomes maximum. As for the generation of plasma, the inner side of the inner antenna 7′ (having a circular shape) is mainly generated by the inner antenna 7′ and the circumference of the outer antenna 7 (having a ring shape) is mainly generated by the outer antenna 7. Therefore, distribution control of plasma can be realized by changing the ratio of absolute values of current |I₁|(=I₂|=|I₃|=|I₄|) and current |I₁′|(=|I₂′|=|I₃′|=|I₄′|). This is a tuning knob that could not be obtained when m=1. The current ratio |I₁′|/|I₁| can be set freely from 0 (|₁′|=0, |I₁| being a finite value) to infinity (|I₁′| being a finite value, |I₁|=0).

According to the present invention, in a single high frequency induction antenna set, the phase of currents within the set of high frequency induction antennas must be controlled, for example as described in FIGS. 2A and 2B. This must be satisfied both in the outer antenna 7 (high frequency induction antenna elements 7-1, 7-2, 7-3 and 7-4) and the inner antenna 7′ (7′-1, 7′-2, 7′-3 and 7′-4) of FIG. 19. Further, according to the example illustrated in FIG. 19, the phase difference of currents supplied to the outer antenna 7 and the inner antenna 7′ is controlled to 0°. However, according to the arrangement of FIG. 19, the phase difference of the inner and outer antennas is not necessarily controlled to 0°. The electric field (magnetic field) is a physical quantity capable of being added and subtracted, and the induction electric field created by the outer antenna and the induction electric field created by the inner antenna are necessarily mutually strengthened in some areas and mutually weakened in other areas. When the phase difference is 0° in FIG. 19, the mutually weakening electric field is minimized and the mutually strengthening electric field is maximized. Therefore, the transfer efficiency of power from the antenna to the plasma is maximized. When the difference is not 0°, the mutually weakening electric field is increased and the mutually strengthening electric field is reduced compared to the case where the difference is 0°. From the viewpoint of plasma distribution control, there is no need to minimize the mutually weakening electric field and to maximize the mutually strengthening electric field. In order to simplify description, the phase difference of currents of the inner antenna and the outer antenna are set to 0°, but it can also be set to other than 0°.

### Embodiment 9

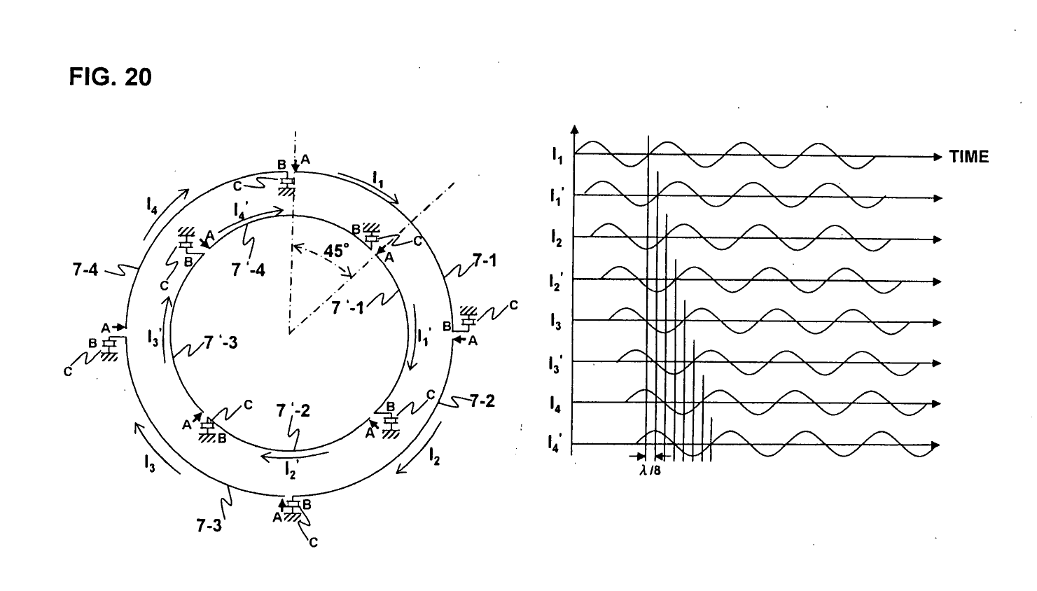

Embodiment 9 will now be described with reference to FIG. 20. FIG. 20 illustrates an embodiment where the phase difference of currents to the outer antenna and the inner antenna is set to 45°. In this case, the number of high frequency induction antenna elements (division number of antenna) is n=4, so 45° corresponds to 2π/mn (radian). In FIG. 20, the inner and outer antennas are displaced by 45° in the circumferential direction so that the electric field generated by the inner antenna 7′ and the outer antenna 7 become strongest. This means, for example, that the power feed end A of the high frequency induction antenna element 7-1 of the outer antenna and the power feed end A of the high frequency induction antenna element 7′-1 of the inner antenna is rotated by 45° in the circumferential direction. According to this arrangement, the phase difference of the currents supplied to the respective high frequency induction antenna elements should be 45° (λ/mn), as shown in the right side of FIG. 20.

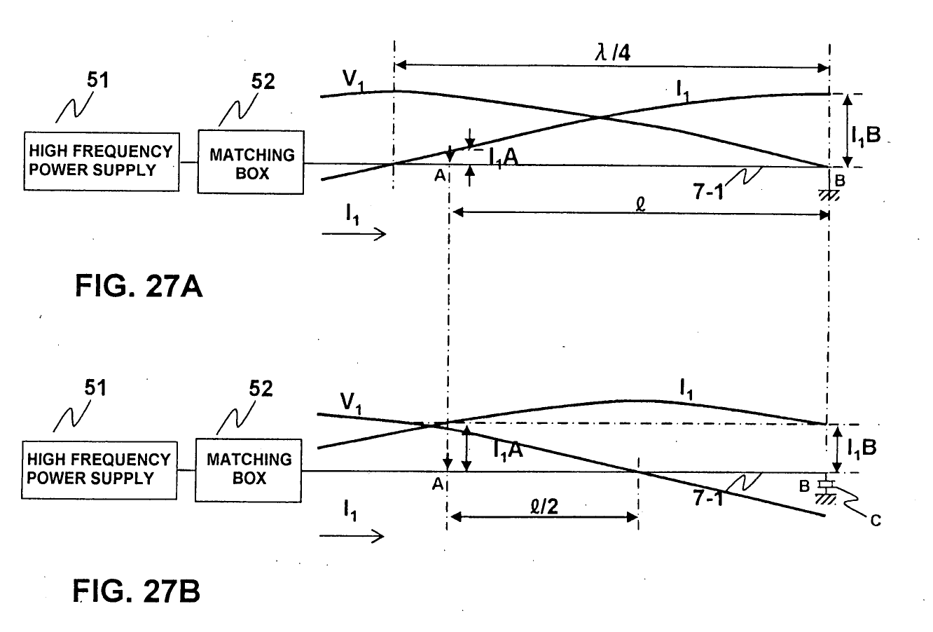

The arrangement of FIG. 20 is advantageous compared to the arrangement of FIG. 19. Therefore, the disadvantages of the arrangement of FIG. 19 will be described. Similar to FIG. 2, the condition for the induction electric field created by the outer antenna 7 of FIG. 19 to rotate smoothly is that the single high frequency induction antenna element, such as the 7-1, has a length 1 satisfying 1≦λ/n (when the outer antenna satisfies 1≦λ/n, the inner antenna necessarily satisfies 1≦λ/n, so only the outer antenna is described here). Now, when 1<<λ/n, the high frequency current I₁A flowing to the power feed end A of the antenna element 7-1 and the high frequency current I₁B flowing to the earth end B can be considered as equal, so that I₁A=I₁B. However, when 1 approximates length λ/n, the standing waves (wavelength λ) create a current distribution within the high frequency induction antenna element. This state is shown in FIG. 27A. The impedance in the I₁ direction observed from power feed end A has a finite impedance of the antenna element 7-1, whereas the impedance in the I₁ direction observed from earth end B is substantially 0Ω. Therefore, when the influence of the standing waves is significant, normally I₁A<I₁B is satisfied, as shown in FIG. 27A. Of course, the electric field intensity directly below the power feed end A, that is, the plasma density, becomes smaller than the plasma density immediately below the earth end B. In other words, plasma distribution occurs in the circumferential direction of the outer antenna. The plasma distribution varies greatest at the joint between antenna elements, that is, for example between the earth end B of the antenna element 7-1 and the power feed end A of the antenna element 7-2 according to FIG. 19.

There are two methods for making the plasma distribution in the circumferential direction more uniform. One method is to earth the earth end B via a capacitor C instead of directly as shown in FIG. 20. By appropriately designing the value of capacitor C, it becomes possible to realize I₁A=I₁B. This state is illustrated in FIG. 27B. When the inductance of the antenna element 7-1 is referred to as L, I₁A=I₁B is realized when the relationship of 1/ωC=ωL/2 is satisfied between capacitor C (capacity C) and L. As shown in FIG. 27B, at this time, the distribution of current I₁ is maximum at the center of the antenna element 7-1, and the distribution of voltage V₁ is 0V at the center of the antenna element 7-1. This is described in detail in non-patent document 4 and non-patent document 3.

Another method is to displace the positions in the circumferential direction of the of the power feed end A and the earth end B of the inner antenna with respect to the circumferential positions of the power feed end A and the earth end B of the outer antenna, in other words, to provide phase angles thereto. In FIG. 20, the phase angle is 45°. According to such arrangement, the various densities of plasma can be dispersed within the chamber and the uniformity of plasma due to diffusion can be improved. The arrangement of FIG. 20 shows one embodiment for simultaneously satisfying the two conditions.

### Embodiment 10

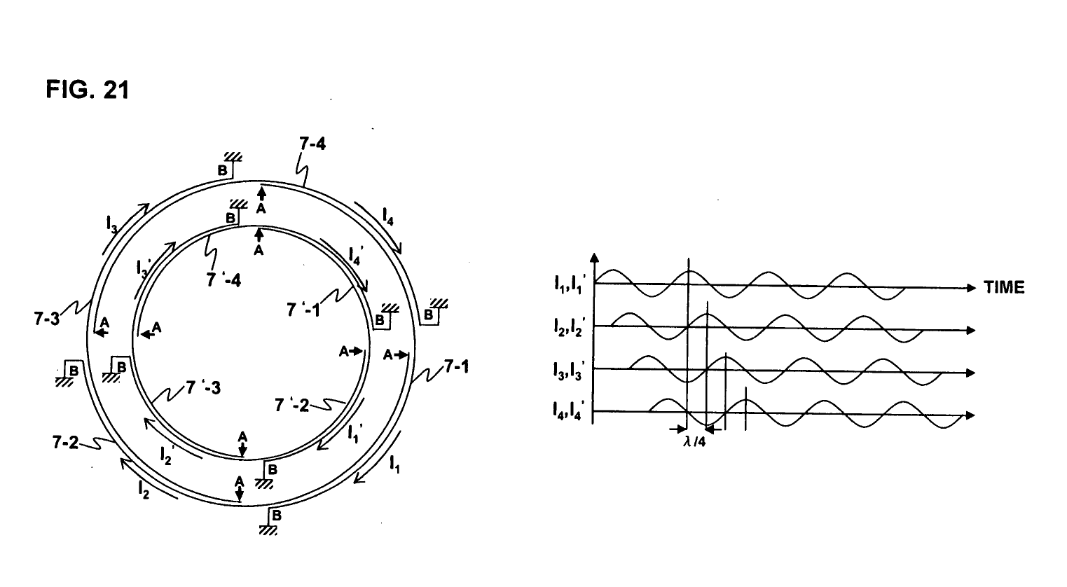

Embodiment 10 will now be described with reference to FIG. 21. When a plasma distribution in the circumferential direction of the antenna is created by the effect of standing waves, another antenna arrangement can be adopted to make the plasma distribution more uniform. This is to superpose the antenna elements, and one embodiment thereof is illustrated in FIG. 21. In FIG. 21, one half of the high frequency induction antenna element 7-1 is superposed with the high frequency induction antenna element 7-4, and the remaining half is superposed with the high frequency induction antenna element 7-2. In the portion where the high frequency induction antenna elements are superposed, induction electric fields generated by the current supplied to the two high frequency induction antenna elements are added. In other words, induction electric field via currents I₁ and I₄ is formed at half of the high frequency induction antenna element 7-1, and the induction electric field via I₁ and I₂ is formed at the other half. Therefore, a rotating electric field can be formed in the state where the induction electric field in the circumference direction is further smoothed. FIG. 21 illustrates an example where this arrangement is applied to all the antenna elements.

The method for forming a more smooth rotating electric field using the outer antenna 7 and the inner antenna 7′ was described with reference to FIGS. 20 and 21. (1) The method for setting a mounting phase angle in the circumference direction of the outer antenna and the inner antenna, (2) the method for grounding the earth end B via a capacitor, and (3) the method for superposing the antenna elements are described via individual drawings, but these methods can also be performed simultaneously.

### Embodiment 11

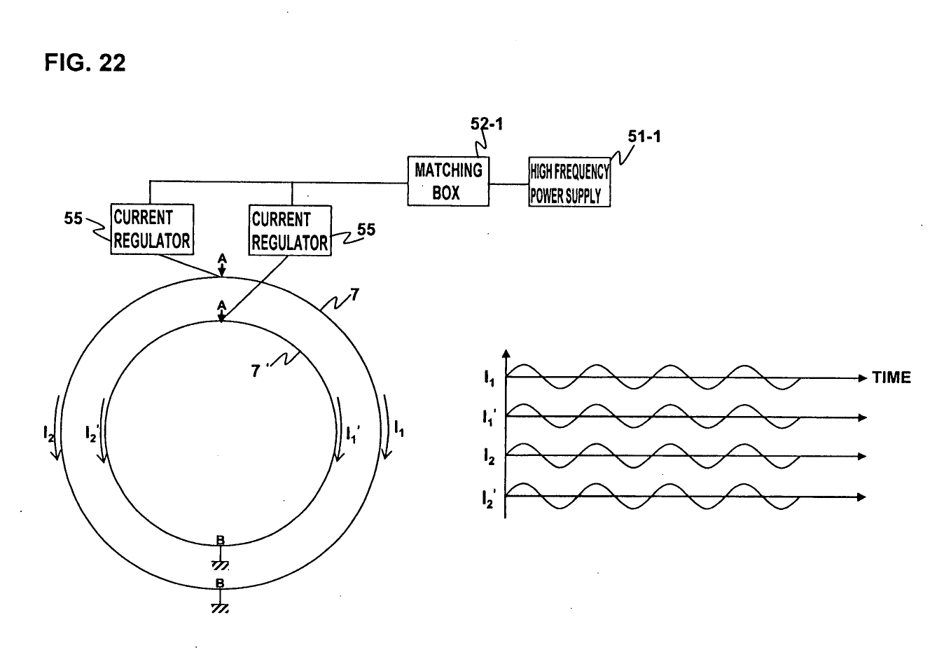

Embodiment 11 will be described with reference to FIG. 22. FIG. 22 shows an example of an arrangement in which the length 1 of the high frequency induction antenna elements is 1<<λ/n, that is, I₁A=I₁B, according to which a most simple m=2 arrangement is realized. This arrangement applies the arrangement illustrated in FIG. 12 to the inner antenna 7′ and the outer antenna 7, respectively. In this example, the currents I₁, I₁′, I₂ and I₂′ supplied to the high frequency induction antenna elements are all currents having the same phase. Therefore, currents can be supplied from a single power supply to the power feed point A of the inner antenna and the power feed point A of the outer antenna. In this case, it is preferable to insert to the illustrated positions current regulators 55 for regulating the amount of currents supplied to the inner antenna and the outer antenna. Of course, it is also possible to supply current from individual power supplies to the inner antenna 7′ and the outer antenna 7.

Similar to the example of a planar vacuum reactor top member 12, even if the vacuum reactor top member 12 formed of insulating material has a rotated trapezoidal shape, a hollow semispherical shape or dome shape, or a cylindrical shape with a bottom, the high frequency induction antennas can be disposed at the inner circumference or the outer circumference thereof, or at vertical or oblique positions. As described with reference to FIGS. 13A through 13E, the positions of the antennas with respect to the vacuum reactor top member 12 are extremely important in controlling the generation distribution and diffusion distribution of plasma. In the same sense, the arrangement of the inner antenna and the outer antenna with respect to the vacuum reactor top member 12 is also extremely important.

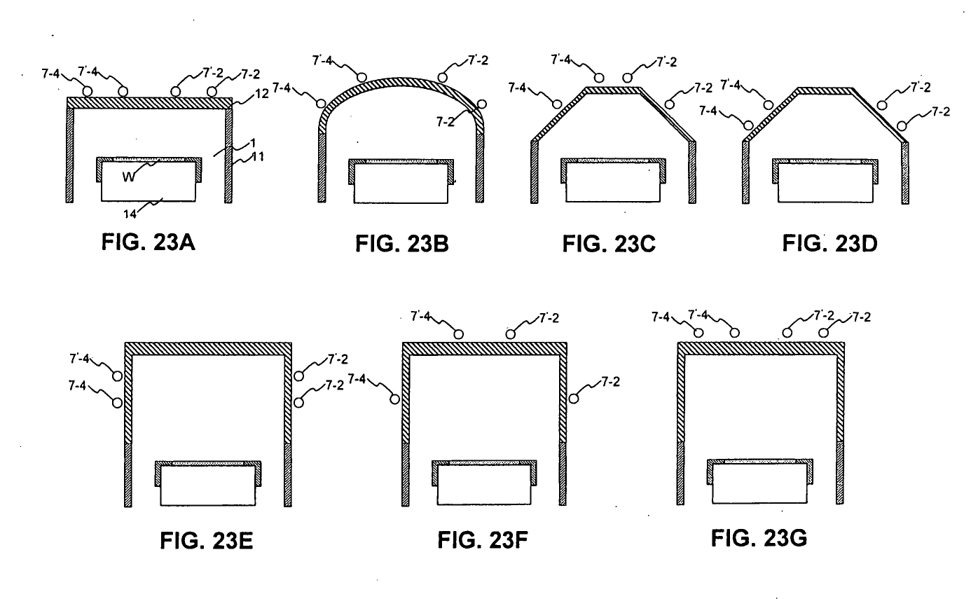

FIGS. 23A through 23G illustrate variations of the arrangements of the inner antenna 7′ and the outer antenna 7 with respect to the vacuum reactor top member 12. FIG. 23A shows an example of the inner antenna 7′ and the outer antenna 7 disposed on top of a planar vacuum reactor top member 12. Compared to FIG. 13A, the present arrangement enables to create a plasma distribution more concentrated at the center area. Of course, if one of the currents supplied to the inner antenna 7′ and the outer antenna 7 is set to 0 A, the arrangements of FIG. 23A and FIG. 13A will be equivalent. Since the planar vacuum reactor top member 12 has a single plane (upper plane), the arrangement will be as illustrated. FIG. 23B shows the variation of arrangement of the inner antenna 7′ and the outer antenna 7 with respect to a hollow semispherical shaped vacuum reactor top member 12. The outer antenna and the inner antenna are arranged on the curved surface of the dome, by which the distribution controllability of plasma is enhanced. Similar to FIG. 23A, when one of the currents of the inner antenna 7′ and the outer antenna 7 is set to 0 A, the arrangements of FIG. 23B and FIG. 13B will be equivalent.

FIGS. 23C and 23D show variations of arrangements of the inner antenna 7′ and the outer antenna 7 with respect to a rotated trapezoidal shaped vacuum reactor top member 12. Since the rotated trapezoidal shaped vacuum reactor top member 12 has a slanted side surface and a flat upper surface, variations illustrated in FIGS. 23C and 23D are enabled. FIG. 23C arranges the outer antenna 7 on the side surface and the inner antenna 7′ on the upper surface. FIG. 23D arranges the inner antenna 7′ and the outer antenna 7 on the slanted side surface. According to FIGS. 23C and 23D, when one of the currents of the inner antenna 7′ and the outer antenna 7 is set to 0 A, the arrangements will be equivalent to FIG. 13D. Further, the arrangement of FIG. 23D is capable of further controlling the plasma distribution at the center portion than the arrangement of FIG. 23C. Although not shown, it is possible to arrange all the antennas on the upper surface.

FIGS. 23E, 23F and 23G illustrate variations of the arrangement of the inner antenna 7′ and the outer antenna 7 with respect to the cylindrical vacuum reactor top member 12. Since the cylindrical vacuum reactor top member 12 has a perpendicular side wall and a wide flat upper surface, variations as illustrated in FIGS. 23E, 23F and 23G are enabled. FIG. 23E has the inner antenna 7′ and the outer antenna 7 arranged on the side wall. FIG. 23F has the outer antenna 7 arranged on the side wall and the inner antenna 7′ arranged on the upper surface. According to FIGS. 23E and 23F, when one of the currents of the inner antenna 7′ and the outer antenna 7 is set to 0 A, the arrangements will be equivalent to FIG. 13E.

FIG. 23G has the outer antenna 7 and the inner antenna 7′ disposed on the upper surface. It seems as though according to the arrangement of FIG. 23G, when one of the currents of the inner antenna 7′ or the outer antenna 7 is set to 0 A, the arrangement will be equivalent to FIG. 13A. However, compared to the arrangement of FIG. 13A where the side wall is a vacuum reactor formed of conductive material (which is earthed), in FIG. 23G, the side wall is formed of a vacuum reactor top member 12 composed of insulating material (which is electrically a float), so that the distribution of the generated induction electric field will differ, and so they are not equivalent. The shapes of the vacuum reactor top member 12 and the number of sets of the high frequency induction antennas and the arrangements thereof as described should be determined based on what type of process the generated plasma is applied to.

The descriptions regarding FIGS. 2, 13, 18 and 23A through 23G will now be summarized. The present invention includes many plasma distribution control functions, including the division number n of the antenna, the shape of the vacuum reactor top member 12, the number of sets m of the high frequency induction antenna, and the arrangement of antennas with respect to the vacuum reactor top member 12. However, these arrangements are also realizable in apparatus arrangements adopting prior art ICP sources. The most important point of the present invention regarding plasma distribution control is that, in addition to the above-mentioned flexible plasma controllability regarding apparatus arrangement, a tuning knob which is an ECR plane that can be controlled electrically from the exterior is introduced. By creating a rotating induction electric field using an ICP source and enabling ECR discharge not only enables advantageous plasma ignition property and enables plasma generation at a lower gas pressure, but also enables to provide a superior plasma controlling ability through the ECR plane controllable from the exterior. Such plasma source having superior flexibility in plasma controlling ability has never been seen in the prior art.

### Embodiment 12

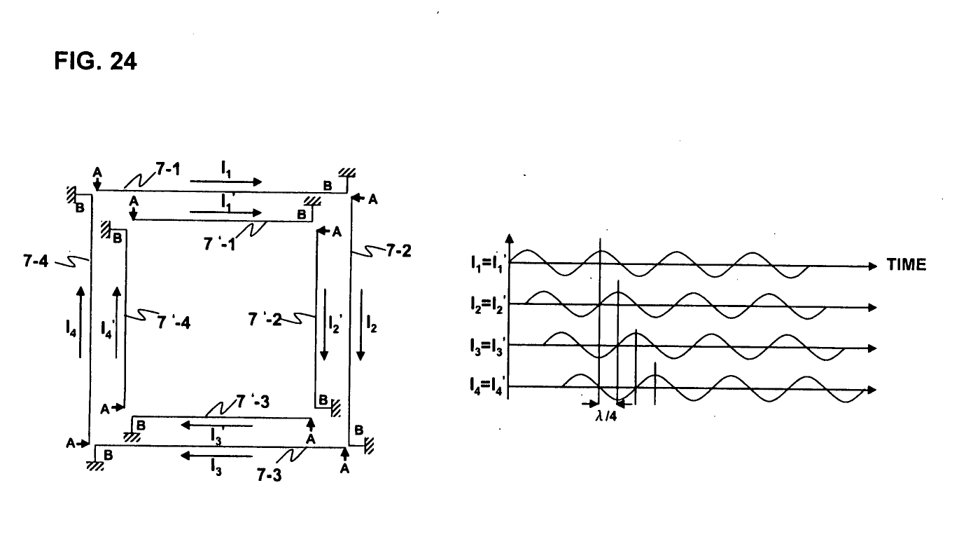

Embodiment 12 of the present invention will be described with reference to FIG. 24. The present embodiment adopts linear elements as the high frequency induction antenna elements 7-1 through 7-4 and 7′-1 through 7′-4 shown in FIG. 19, wherein the outer antenna 7 and the inner antenna 7′ of the respective sets is arranged in a rectangle. FIG. 24 illustrates the arrangement of a high frequency induction antenna with the division number of antenna set to n=4 and the number of antenna sets set to m=2. High frequency induction antenna elements 7-1 through 7-4 arranged linearly and divided are disposed as the outer antenna 7, wherein since the division number of the antenna is four, they constitute a square (rectangle). The inner antenna 7′ is arranged in a similar manner. This embodiment can be considered to have the antenna arrangement illustrated in FIG. 19 changed to a rectangular shape. However, by adopting a rectangular shape, a rectangular induction electric field will be rotated. It can be recognized that the shape of the electric field which was circular according to FIGS. 3A and 3B has been changed to a square shape. However, a completely rectangular electric field distribution does not exist. This is because the electric field is always composed of differentiable curved surfaces. However, the arrangement of FIG. 24 has an effect in that the collapse from a square shape of the induction electric field distribution created by the inner antenna is compensated by the outer electrode. In FIG. 24, the phase difference of currents of the inner antenna and the outer antenna is 0°, but it can be set to values other than 0°, similar to FIG. 19.

### Embodiment 13

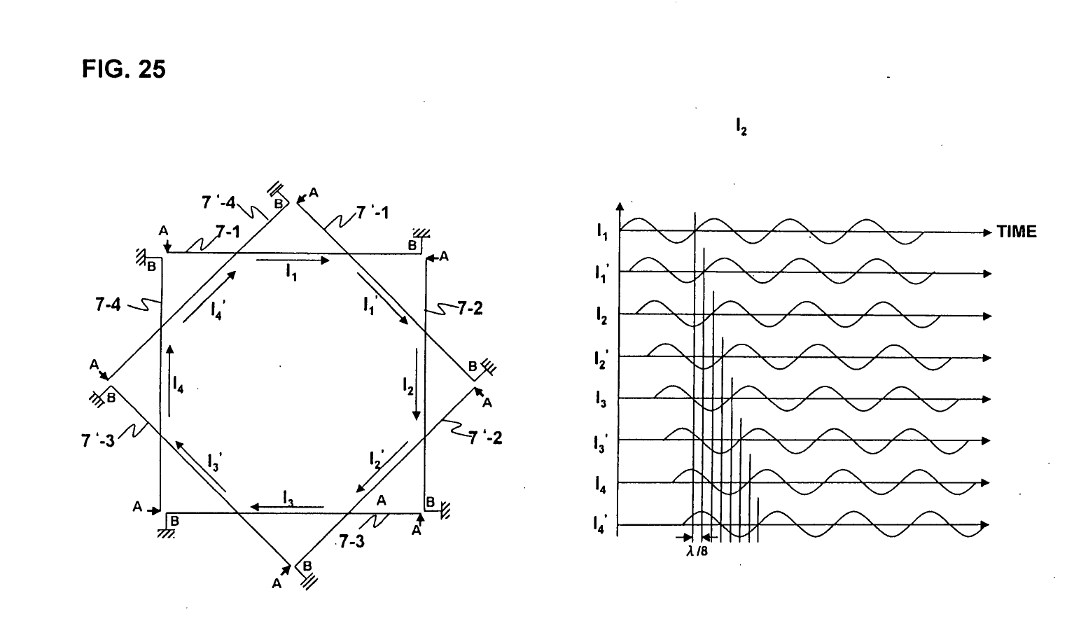

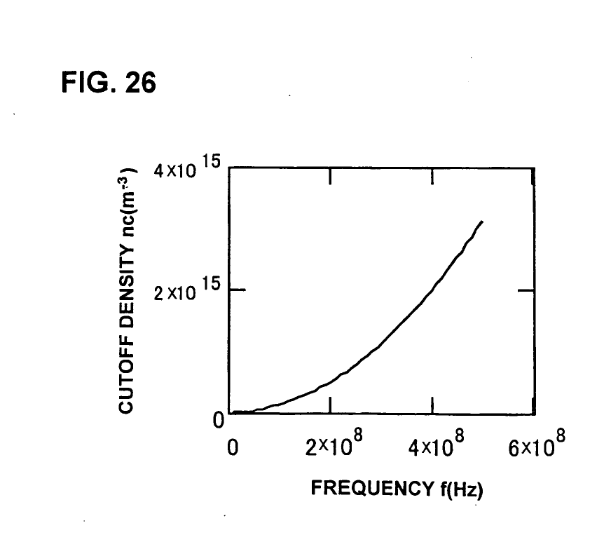

Embodiment 13 of the present invention will be described with reference to FIG. 25. This is an embodiment related to the high frequency induction antenna arrangement designed to enable the induction electric field to be rotated as a rectangle without having the square shape collapsed so much compared to FIG. 24. The present arrangement adopts the concept described with reference to FIG. 20 to a shape with n-sides, wherein the phases of currents supplied to the respective antenna elements will be the same as FIG. 20. In other words, the outer (first) antenna 7 composed of high frequency induction antenna elements 7-1 through 7-4 and the inner (second) antenna 7′ composed of high frequency induction antenna elements 7′-1 through 7′-4 are mutually displaced by 45°, by which an induction electric field rotating in the right direction is formed. The first antenna 7 includes linear high frequency induction antenna elements 7-1 through 7-4 arranged in a rectangle. The high frequency induction antenna elements 7-1 through 7-4 respectively receive supply of currents with a λ/4 phase difference from the power feed ends A, and the earth ends B are earthed. Similarly, the second antenna 7′ includes linear high frequency induction antenna elements 7′-1 through 7′-4 arranged in a rectangle. The high frequency induction antenna elements 7′-1 through 7′-4 respectively receive supply of currents with a λ/4 phase difference from the power feed ends A, and the earth ends B are earthed. Currents sequentially λ/8 phase angle displaced are supplied to the corresponding high frequency induction antenna elements 7-1 and 7′-1, and similarly, currents sequentially λ/8 phase angle displaced are supplied to other corresponding high frequency induction antenna elements 7-2 and 7′-2, elements 7-3 and 7′-3 and elements 7-4 and 7′-4. The first antenna 7 and the second antenna 7′ are vertically superposed, and are mutually displaced by 45°. According to this arrangement, currents I₁, I₁′, I₂, I₂′, I₃, I₃′, I₄ and I₄′ having λ/8 phase displacements are supplied to adjacent high frequency induction antenna elements, by which an induction electric field rotated in the right direction and having a shape closer to a rectangular shape compared to the arrangement of FIG. 24 can be formed.

What is claimed is:

1. A plasma processing apparatus comprising a vacuum reactor constituting a vacuum processing chamber for housing a sample, a gas supply port for introducing a processing gas into the vacuum processing chamber, a high frequency induction antenna disposed outside the vacuum processing chamber, a magnetic field coil for forming a magnetic field with in the vacuum processing chamber, a plasma generating high frequency power supply for supplying high frequency current to the high frequency induction antenna, and a power supply for supplying power to the magnetic field coil, wherein high frequency current from the high frequency power supply is supplied to the high frequency induction antenna so as to turn the gas supplied to the vacuum processing chamber into plasma for subjecting the sample to plasma processing, wherein
the vacuum processing chamber comprises a vacuum processing chamber top member fixed air tightly to an upper portion of the vacuum reactor, the vacuum processing chamber top member composed of a dielectric material and having a planar shape, a hollow semispherical shape, a rotated trapezoidal shape, or a cylindrical shape with a bottom; and
the high frequency induction antenna is divided into n (n being an integer of n≧2) high frequency induction antenna elements, the divided high frequency induction antenna elements being arranged tandemly on a circumference, wherein high frequency currents sequentially delayed by λ(wavelength of the high frequency power supply)/n are supplied in a fixed direction to the respective tandemly arranged high frequency induction antenna elements, so as to form via the high frequency currents a rotating induction electric field E rotating in a right direction with respect to a direction of line of magnetic force of a magnetic field B formed by supplying power to the magnetic field coil, the rotating induction electric field E having a rotation frequency corresponding to an electron cyclotron frequency of the magnetic field B, and the multiple antennas and the magnetic field are arranged so that the induction electric field E and the magnetic field B satisfy a relationship of E×B≠0 so as to generate plasma, the plasma being used to subject the sample to plasma processing.

2. A plasma generating apparatus comprising a vacuum processing chamber having at an upper portion thereof a vacuum processing chamber top member formed of an insulating material having a planar shape, a rotated trapezoidal shape, a hollow semispherical shape, or a cylindrical shape with a bottom, a plurality of high frequency induction antennas disposed outside the vacuum processing chamber and through which high frequency is supplied, the plurality of antennas being arranged on a single plane and symmetrically with respect to an axis orthogonal to said plane, a magnetic field distribution having a symmetric distribution with respect to an axis crossing said plane and orthogonal to said plane, the axis of the multiple antennas corresponding to the axis of the magnetic field distribution, wherein the multiple antennas and the magnetic field are arranged so that a rotation frequency of the rotating induction electric field E formed by the multiple antennas is set to correspond to the electron cyclotron frequency of the magnetic field B so that the induction electric field distribution formed in the vacuum processing chamber rotates in a fixed direction, and that the induction electric field E formed by the multiple antennas and the magnetic field B satisfy a relationship of E×B≠0.

3. The plasma generating apparatus according to claim 2, wherein
the rotating direction of the induction electric field distribution rotating in a fixed direction is a right direction with respect to the direction of the line of magnetic force of the magnetic field.

4. The plasma generating apparatus according to claim 2, wherein
the rotation frequency of the rotating induction electric field E formed via the multiple antennas is set to correspond to the electron cyclotron frequency of the magnetic field B.

5. The plasma generating apparatus according to claim 2, wherein
a variation frequency f_{B} of the magnetic field B is set to satisfy a relationship of 2πf_{B}<<ωc with respect to a rotation frequency (electron cyclotron frequency ω_{c}) of Larmor motion.
